(19) United States
(12) Patent Application Publication
(10) Pub. No.: US 2026/0090110 A1
(43) Pub. Date: Mar. 26, 2026

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Byeol Hae EOM, Suwon-si (KR); Myung Gil Kang, Suwon-si (KR); Tae Woo Uhm, Suwon-si (KR)

(73) Assignee: SAMSUNG ELECTRONICS CO., LTD., Suwon-si (KR)

(21) Appl. No.: 19/213,415

(22) Filed: May 20, 2025

(30) Foreign Application Priority Data
Sep. 25, 2024 (KR) 10-2024-0129567

(51) Int. Cl. H10D 89/60

(52) U.S. Cl. CPC H10D 89/611

(57) ABSTRACT

A semiconductor device may include a stacked structure including: a bulk semiconductor pattern including a first well region; a sacrificial film on an upper surface of the bulk semiconductor pattern; and a semiconductor film on an upper surface of the sacrificial film. The semiconductor device may further include: a device isolation pattern on a side of the stacked structure; and a backside wiring structure on a lower surface of the bulk semiconductor pattern and a lower surface of the device isolation pattern, wherein the stacked structure further includes a first doping region that extends across the bulk semiconductor pattern, the sacrificial film, and the semiconductor film, and the first doping region is connected to the first well region, and wherein the first doping region is spaced apart from the lower surface of the bulk semiconductor pattern.

### CROSS-REFERENCE TO RELATED APPLICATION

This application claims priority from Korean Patent Application No. 10-2024-0129567, filed on Sep. 25, 2024, in the Korean Intellectual Property Office, and all the benefits accruing therefrom under 35 U.S.C. 119, the disclosure of which is herein incorporated by reference in its entirety.

### BACKGROUND

### 1. Field

Some embodiments of the present disclosure relate to a semiconductor device and a method for fabricating the same, and more particularly, to a semiconductor device including a passive device and a method for fabricating the same.

### 2. Brief Description of Background Art

As one of scaling techniques for increasing a density of an integrated circuit device, a multi-gate transistor for forming a silicon body having a fin shape or a nanowire shape on a substrate and forming a multi-gate on a surface of the silicon body has been suggested.

Since this multi-gate transistor uses a three-dimensional channel, it is easy to scale the multi-gate transistor. Also, even though a gate length of the multi-gate transistor is not increased, a current control capability may be improved. In addition, a short channel effect (SCE) in which a potential of a channel region is affected by a drain voltage may be suppressed effectively.

### BRIEF SUMMARY

According to embodiments of the present disclosure, a semiconductor device may be provided that includes a passive device with improved compatibility with a back side power delivery network (BSPDN).

According to embodiments of the present disclosure, a method for fabricating a semiconductor device may be provided, in which a semiconductor device with improved yield and performance may be fabricated.

According to embodiments of the present disclosure, a semiconductor device may include a stacked structure including: a bulk semiconductor pattern including a first well region; a sacrificial film on an upper surface of the bulk semiconductor pattern; and a semiconductor film on an upper surface of the sacrificial film. The semiconductor device may further include: a device isolation pattern on a side of the stacked structure; and a backside wiring structure on a lower surface of the bulk semiconductor pattern and a lower surface of the device isolation pattern, wherein the stacked structure further includes a first doping region that extends across the bulk semiconductor pattern, the sacrificial film, and the semiconductor film, and the first doping region is connected to the first well region, and wherein the first doping region is spaced apart from the lower surface of the bulk semiconductor pattern.

According to embodiments of the present disclosure, a semiconductor device may include a stacked structure including: a bulk semiconductor pattern including a first well region having a first conductivity type; a sacrificial film on an upper surface of the bulk semiconductor pattern; and a semiconductor film on an upper surface of the sacrificial film. The semiconductor device may further include: a device isolation pattern on a side of the stacked structure; and a gate structure on the stacked structure and the device isolation pattern, and crossing the stacked structure, wherein the stacked structure further includes a first doping region on a first side of the gate structure, the first doping region connected to the first well region and having a second conductivity type different from the first conductivity type, and wherein the first doping region extends across the bulk semiconductor pattern, the sacrificial film, and the semiconductor film.

According to embodiments of the present disclosure, a semiconductor device may include a stacked structure in a first region of the semiconductor device, the stacked structure including: a bulk semiconductor pattern; a sacrificial film on an upper surface of the bulk semiconductor pattern; and a first semiconductor film on an upper surface of the sacrificial film. The semiconductor device may further include: an active pattern including a fin-type pattern and a second semiconductor film in a second region of the semiconductor device, the fin-type pattern extending in a first direction, and the second semiconductor film extending in the first direction and spaced apart from an upper surface of the fin-type pattern; a device isolation pattern on a side of the bulk semiconductor pattern and a side of the fin-type pattern; a first gate structure on the stacked structure and the device isolation pattern, and crossing the stacked structure; a second gate structure on the active pattern and the device isolation pattern, and extending in a second direction crossing the first direction; and a backside wiring structure on a lower surface of the bulk semiconductor pattern, a lower surface of the fin-type pattern, and a lower surface of the device isolation pattern, wherein the bulk semiconductor pattern and the fin-type pattern are at a same level as each other, wherein the first semiconductor film and the second semiconductor film are at a same level as each other, and wherein the stacked structure further includes a PN junction at a level between the lower surface of the device isolation pattern and the upper surface of the bulk semiconductor pattern.

Aspects of embodiments of the present disclosure are not limited to those mentioned above, and additional aspects of embodiments of the present disclosure, which are not mentioned herein, will be clearly understood by those skilled in the art from the following description of the present disclosure.

### BRIEF DESCRIPTION OF DRAWINGS

The above and other aspects and features of the present disclosure will become more apparent by describing in detail non-limiting example embodiments thereof with reference to the attached drawings, in which:

FIG. 1 is an example layout view illustrating a semiconductor device according to some embodiments.

FIG. 2 is a cross-sectional view taken along a line A1-A1 of FIG. 1.

FIG. 3 is a cross-sectional view taken along a line B1-B1 of FIG. 1.

FIG. 4 is a cross-sectional view taken along a line C1-C1 of FIG. 1.

FIGS. 5 to 10 are various other cross-sectional views illustrating a semiconductor device according to some embodiments.

FIG. 11 is an example layout view illustrating a semiconductor device according to some embodiments.

FIG. 12A illustrates a cross-sectional view taken along a line A1-A1 of FIG. 11.

FIG. 12B illustrates a cross-sectional view taken along a line A2-A2 of FIG. 11.

FIG. 13A illustrates a cross-sectional view taken along a line B1-B1 of FIG. 11.

FIG. 13B illustrates a cross-sectional view taken along a line B2-B2 of FIG. 11.

FIG. 14A illustrates a cross-sectional view taken along a line C1-C1 of FIG. 11.

FIG. 14B illustrates a cross-sectional view taken along a line C2-C2 of FIG. 11.

FIGS. 15 to 36B are views illustrating intermediate steps to describe a method for fabricating a semiconductor device according to some embodiments.

### DETAILED DESCRIPTION

It will be understood that, although the terms “first,” “second,” etc., may be used herein to describe various elements, these elements should not be limited by these terms. These terms are only used to distinguish one element from another element. Thus, for example, a first element, a first component, or a first section discussed below could be termed a second element, a second component, or a second section without departing from the spirit and scope of the present disclosure.

As used herein, “equal” means not only “exactly equal” but also including a minor difference that may occur due to a process margin, etc.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

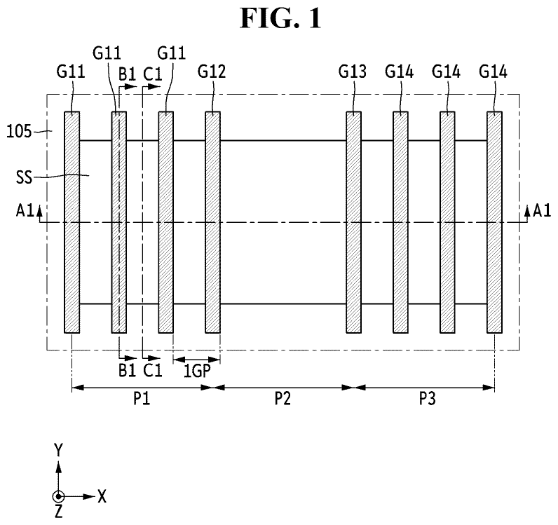

Hereinafter, a semiconductor device according to example embodiments will be described with reference to FIGS. 1 to 14.

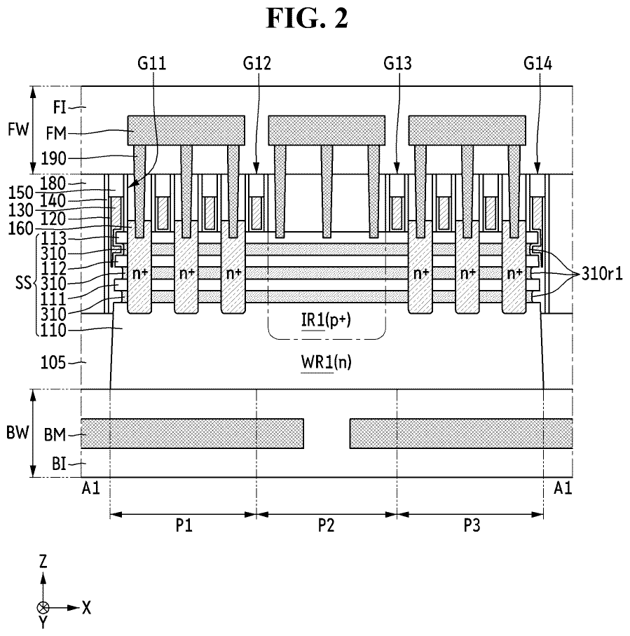

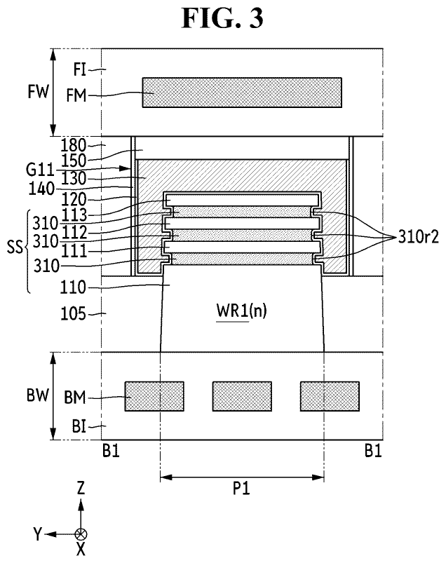

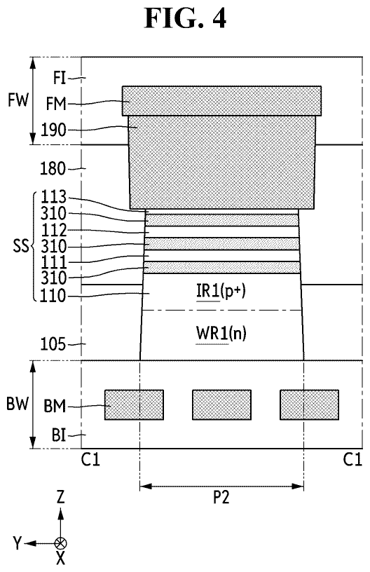

FIG. 1 is an example layout view illustrating a semiconductor device according to some embodiments. FIG. 2 is a cross-sectional view taken along a line A1-A1 of FIG. 1. FIG. 3 is a cross-sectional view taken along a line B1-B1 of FIG. 1. FIG. 4 is a cross-sectional view taken along a line C1-C1 of FIG. 1.

Referring to FIGS. 1 to 4, a semiconductor device according to some embodiments includes a stacked structure SS, a first device isolation pattern 105, first to fourth gate structures G11 to G14, a first epitaxial pattern 160, a first interlayer insulating film 180, a front wiring structure FW, and a backside wiring structure BW.

The stacked structure SS may include a bulk semiconductor pattern 110, a plurality of first sacrificial films 310, and a plurality of first semiconductor films 111 to 113.

The bulk semiconductor pattern 110 may be a bulk silicon pattern, or may include another material such as, for example, silicon germanium, indium antimonide, lead telluride, indium arsenide, indium phosphide, gallium arsenide, or gallium antimonide. The bulk semiconductor pattern 110 may be formed by etching a portion of a base substrate, or may be an epitaxial layer grown from the base substrate. In the following description, the bulk semiconductor pattern 110 is a silicon (Si) pattern by way of example.

In some embodiments, the bulk semiconductor pattern 110 may include a first well region WR1 having a first conductivity type. For example, the first well region WR1 may be an n-type doping region “n” formed by doping n-type impurities (e.g., phosphorus (P), antimony (Sb), or arsenic (As) in the bulk semiconductor pattern 110. Although the first conductivity type is described as an n-type in the following description, this is only an example, and the first conductivity type may be a p-type.

The plurality of first sacrificial films 310 and the plurality of first semiconductor films 111 to 113 may be alternately stacked on an upper surface of the bulk semiconductor pattern 110. For example, each of the first sacrificial films 310 and each of the first semiconductor films 111 to 113 may have a layered structure extended along a horizontal plane (e.g., XY plane) parallel with the upper surface of the bulk semiconductor pattern 110. The first semiconductor films 111 to 113 may be sequentially stacked by being spaced apart from one another by the first sacrificial films 310. The number, arrangement, and thickness of the first sacrificial films 310 and the first semiconductor films 111 to 113 are only examples, and are not limited thereto.

Each of the first semiconductor films 111 to 113 may include silicon (Si) or germanium (Ge), which is a semiconductor material. Alternatively, each of the first semiconductor films 111 to 113 may include a compound semiconductor such as, for example, a group IV-IV compound semiconductor or a group III-V compound semiconductor. The group IV-IV compound semiconductor may be a binary compound or ternary compound, which includes at least two from among carbon (C), silicon (Si), germanium (Ge), and tin (Sn), or a compound including at least two from among carbon (C), silicon (Si), germanium (Ge), and tin (Sn), which are doped with a group IV element. The group III-V compound semiconductor may be, for example, one from among a binary compound, a ternary compound, and a quaternary compound, which is formed by combination of at least one from among aluminum (Al), gallium (Ga), and indium (In), which is a group III element, and at least one from among phosphorus (P), arsenic (As), and antimony (Sb), which is a group V element. In the following description, each of the first semiconductor films 111 to 113 is a silicon (Si) film, as an example.

The first sacrificial films 310 may include a material having etch selectivity with respect to the first semiconductor films 111 to 113. For example, each of the first semiconductor films 111 to 113 may be a silicon (Si) film, and each of the first sacrificial films 310 may be a silicon germanium (SiGe) film.

Although the stacked structure SS is shown as being elongated in a first direction X, this is only an example. The stacked structure SS may be elongated in a second direction Y crossing the first direction X.

The first device isolation pattern 105 may cover at least a portion of a side of the stacked structure SS. For example, as shown, the first device isolation pattern 105 may cover a portion of a side of the bulk semiconductor pattern 110. In some embodiments, the first device isolation pattern 105 may be a shallow isolation trench (STI) formed by filling an insulating material in at least a portion of a shallow trench formed in the stacked structure SS. Although an upper portion of the bulk semiconductor pattern 110 is shown as protruding above the uppermost surface of the first device isolation pattern 105, this is only an example. As another example, the uppermost surface of the bulk semiconductor pattern 110 may be positioned to be coplanar with the uppermost surface of the first device isolation pattern 105.

A lower surface of the bulk semiconductor pattern 110 may be positioned to be coplanar with or higher than a lower surface of the first device isolation pattern 105. For example, the lower surface of the bulk semiconductor pattern 110 may not be lower than the lower surface of the first device isolation pattern 105. In some embodiments, as shown, the lower surface of the bulk semiconductor pattern 110 may be positioned to be coplanar with the lower surface of the first device isolation pattern 105.

The first device isolation pattern 105 may include an insulating material such as, for example, at least one from among silicon oxide, silicon nitride, silicon oxynitride, and combinations thereof but is not limited thereto. For example, the first device isolation pattern 105 may include a silicon oxide layer.

The first to fourth gate structures G11 to G14 may be formed on the stacked structure SS and the first device isolation pattern 105. For example, the first to fourth gate structures G11 to G14 may extend along an upper surface of the first device isolation pattern 105, and a side and an upper surface of the stacked structure SS. Each of the first to fourth gate structures G11 to G14 may cross the stacked structure SS. For example, each of the first to fourth gate structures G11 to G14 may be elongated in the second direction Y. The first sacrificial films 310 and the first semiconductor films 111 to 113 may extend in the first direction X to pass through the first to fourth gate structures G11 to G14, respectively.

The first gate structure G11, the second gate structure G12, the third gate structure G13, and the fourth gate structure G14 may extend parallel to each other on the stacked structure SS. For example, the stacked structure SS may include a first portion P1, a second portion P2, and a third portion P3, which are sequentially arranged along the first direction X. The first gate structure G11 may be formed on the first portion P1 of the stacked structure SS. The second gate structure G12 may be formed on a boundary between the first portion P1 and the second portion P2 of the stacked structure SS. The third gate structure G13 may be formed on a boundary between the second portion P2 and the third portion P3 of the stacked structure SS. The fourth gate structure G14 may be formed on the third portion P3 of the stacked structure SS.

In some embodiments, a plurality of first gate structures G11 may be formed on the first portion P1 of the stacked structure SS. In some embodiments, some of the plurality of first gate structures G11 may be formed on an end of the first portion P1 of the stacked structure SS.

In some embodiments, a plurality of fourth gate structures G14 may be formed on the third portion P3 of the stacked structure SS. In some embodiments, some of the plurality of fourth gate structures G14 may be formed on an end of the third portion P3 of the stacked structure SS.

Each of the first to fourth gate structures G11 to G14 may include a first gate dielectric film 120, a first gate electrode 130, a first gate spacer 140, and a first gate capping film 150.

The first gate dielectric film 120 may be formed on the stacked structure SS. The first gate dielectric film 120 may be interposed between the stacked structure SS and the first gate electrode 130. For example, the first gate dielectric film 120 may extend such as to be conformal along a profile of the side and upper surface of the stacked structure SS. In some embodiments, the first gate dielectric film 120 may further extend along the upper surface of the first device isolation pattern 105.

The first gate dielectric film 120 may include a dielectric material such as, for example, at least one from among silicon oxide, silicon oxynitride, silicon nitride, and a high dielectric constant material having a dielectric constant greater than a dielectric constant of silicon oxide. The high dielectric constant material may include at least one from among, for example, hafnium oxide, hafnium silicon oxide, hafnium aluminum oxide, lanthanum oxide lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof, but is not limited thereto.

The first gate electrode 130 may be stacked on the first gate dielectric film 120. Each of the first sacrificial films 310 and the first semiconductor films 111 to 113 may extend in the first direction X to pass through the first gate electrode 130. The first gate electrode 130 may include a conductive material such as, for example, at least one from among TiN, WN, TaN, Ru, TiC, TaC, Ti, Ag, Al, TiAl, TiAlN, TiAlC, TaCN, TaSiN, Mn, Zr, W, Al, and combinations thereof, but is not limited thereto.

Although the first gate electrode 130 is shown as a single film, this is only an example, and may be formed by stacking a plurality of conductive films. For example, the first gate electrode 130 may include a work function adjusting film for adjusting a work function and a filling conductive film for filling a space formed by the work function adjusting film. The work function adjusting film may include, for example, at least one from among TiN, TaN, TiC, TaC, TiAlC, and combinations thereof. The filling conductive film may include, for example, W or Al.

The first gate spacer 140 may extend along a side of the first gate electrode 130. Each of the first sacrificial films 310 and the first semiconductor films 111 to 113 may extend in the first direction X to pass through the first gate spacer 140. The first gate spacer 140 may include an insulating material such as, for example, at least one from among silicon oxide, silicon nitride, silicon oxynitride, silicon oxycarbide, silicon boron nitride, silicon boron carbonitride, silicon oxycarbonitride, and combinations thereof, but is not limited thereto.

In some embodiments, a portion of the first gate dielectric film 120 may be interposed between the first gate electrode 130 and the first gate spacer 140. For example, a portion of the first gate dielectric film 120 may extend along an inner side of the first gate spacer 140.

The first gate capping film 150 may extend along an upper surface of the first gate electrode 130. The first gate capping film 150 may include an insulating material, for example, at least one of silicon oxide, silicon nitride, silicon oxynitride, silicon oxycarbide, silicon boron nitride, silicon boron carbonitride, silicon oxycarbonitride, and combinations thereof, but is not limited thereto.

The stacked structure SS may include a first doping region IR1 having a second conductivity type different from the first conductivity type. For example, the first doping region IR1 may be a heavily doped p-type doping region p+ formed by doping heavily doped p-type impurities (e.g., boron (B), indium (In), gallium (Ga), or aluminum (Al)) in the stacked structure SS.

The first doping region IR1 may be formed across the bulk semiconductor pattern 110, the first sacrificial films 310, and the first semiconductor films 111 to 113. The first doping region IR1 may be directly connected to the first well region WR1. Therefore, the first well region WR1 and the first doping region IR1 may form a PN junction in the bulk semiconductor pattern 110.

In some embodiments, the first doping region IR1 may be formed in the second portion P2 of the stacked structure SS. For example, the first doping region IR1 may be formed in the stacked structure SS between the second gate structure G12 and the third gate structure G13.

In some embodiments, the second gate structure G12 and the third gate structure G13 may be spaced apart from each other at an interval greater than one gate pitch 1GP. In this case, the one gate pitch 1GP may be defined as a sum of a minimum interval between gate structures (e.g., between the first gate structure G11 and the second gate structure G12) and a width of one gate structure (e.g., the second gate structure G12).

In some embodiments, the first doping region IR1 may be spaced apart from the lower surface of the bulk semiconductor pattern 110. For example, a lower portion (e.g., a lowermost surface) of the first doping region IR1 may be positioned at a level between the lower surface of the bulk semiconductor pattern 110 and the upper surface of the bulk semiconductor pattern 110.

In some embodiments, a side of each of the first sacrificial films 310, which faces the first to fourth gate structures G11 to G14, may be recessed, past the sides of the first semiconductor films 111 to 113, toward the inside of the stacked structure SS.

For example, as shown in FIG. 2, the side of each of the first sacrificial films 310, which crosses the first direction X, may include a first recess 310r1. The first recess 310r1 may face the first gate structure G11 formed on the end of the first portion P1 and/or the fourth gate structure G14 formed on the end of the third portion P3. Also, the first recess 310r1 may be recessed, past the sides of the first semiconductor films 111 to 113 which cross the first direction X, toward the inside of the stacked structure SS. The first gate dielectric film 120 and/or the first gate electrode 130 may fill at least a portion of the first recess 310r1. In some embodiments, the first recess 310r1 may include a concave surface that is concave toward the first gate structure G11 and/or the fourth gate structure G14, which is/are opposite thereto.

Alternatively or additionally, for example, as shown in FIG. 3, the side of each of the first sacrificial films 310, which crosses the second direction Y, may include a second recess 310r2. The second recess 310r2 may face the first to fourth gate structures G11 to G14. Also, the second recess 310r2 may be recessed, past sides of the first semiconductor films 111 to 113 which cross the second direction Y, toward the inside of the stacked structure SS. The first gate dielectric film 120 and/or the first gate electrode 130 may fill at least a portion of the second recess 310r2. In some embodiments, the second recess 310r2 may include a concave surface that is concave toward the first to fourth gate structures G11 to G14, which are opposite thereto.

The first epitaxial pattern 160 may be formed on the stacked structure SS. In some embodiments, the first epitaxial pattern 160 may be formed on the first portion P1 of the stacked structure SS and the third portion P3 of the stacked structure SS. For example, the first epitaxial pattern 160 may be formed in the stacked structure SS on at least one side of the first gate structure G11 and at least one side of the fourth gate structure G14. The first epitaxial pattern 160 may be connected to the upper surface of the bulk semiconductor pattern 110, the sides of the first sacrificial films 310, and the sides of the first semiconductor films 111 to 113. The first epitaxial pattern 160 may be separated from the first gate electrode 130 by the first gate dielectric film 120 and/or the first gate spacer 140. In some embodiments, a lowermost surface of the first epitaxial pattern 160 may be positioned to be lower than the uppermost surface of the bulk semiconductor pattern 110.

The first epitaxial pattern 160 may include an epitaxial layer doped with impurities. For example, the first epitaxial pattern 160 may be an epitaxial layer grown from the bulk semiconductor pattern 110, the first sacrificial films 310, and the first semiconductor films 111 to 113 by an epitaxial growth process.

In some embodiments, the first epitaxial pattern 160 may have the first conductivity type. For example, the first epitaxial pattern 160 may include n-type impurities (e.g., P, Sb or As) and/or impurities for preventing diffusion of the n-type impurities.

In some embodiments, the first epitaxial pattern 160 may further include a tensile stress material. For example, when each of the first semiconductor films 111 to 113 is a silicon (Si) film, the first epitaxial pattern 160 may include a material (e.g., silicon carbide (SiC) having a lattice constant smaller than a lattice constant of silicon (Si).

The first epitaxial pattern 160 may be directly connected to the first well region WR1. In some embodiments, a doping concentration of the first epitaxial pattern 160 may be greater than a doping concentration of the first well region WR1. For example, the first epitaxial pattern 160 may be a heavily doped n-type doping region n+ formed by doping heavily doped n-type impurities.

The first interlayer insulating film 180 may be formed on the stacked structure SS, the first device isolation pattern 105, the first to fourth gate structures G11 to G14, and the first epitaxial pattern 160. The first interlayer insulating film 180 may be formed to fill a space on outer sides of the first to fourth gate structures G11 to G14.

The first interlayer insulating film 180 may include at least one from among, for example, silicon oxide, silicon nitride, silicon oxynitride, silicon oxycarbide, silicon boron nitride, silicon boron carbonitride, silicon oxycarbonitride, and a low dielectric constant material having a dielectric constant smaller than a dielectric constant of silicon oxide. The low dielectric constant material may include at least one from among Flowable Oxide (FOX), Torene SilaZene (TOSZ), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), Carbon Doped silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material, and combinations thereof, but is not limited thereto.

The front wiring structure FW may be formed on an upper surface of the first interlayer insulating film 180. For example, the front wiring structure FW may include a front inter-wire insulating film FI covering the upper surface of the first interlayer insulating film 180, and front wiring patterns FM in the front inter-wire insulating film FI. The front wiring patterns FM may be insulated from each other while being spaced apart from each other by the front inter-wire insulating film FI. The number, the number of layers, shape, arrangement, etc., of the front wiring patterns FM are only examples, and are not limited to the shown example.

The backside wiring structure BW may be formed on the lower surface of the bulk semiconductor pattern 110 and the lower surface of the first device isolation pattern 105. For example, the backside wiring structure BW may include a backside inter-wiring insulating film BI covering the lower surface of the bulk semiconductor pattern 110 and the lower surface of the first device isolation pattern 105, and backside wiring patterns BM in the backside inter-wiring insulating film BI. The backside wiring patterns BM may be insulated from each other while being spaced apart from each other by the backside inter-wiring insulating film BI. The number, number of layers, shape, arrangement, etc., of the backside wiring patterns BM are only examples, and are not limited to the shown example.

The first epitaxial pattern 160 may be electrically connected to the front wiring structure FW and/or the backside wiring structure BW. For example, a first contact pattern 190 connecting the first epitaxial pattern 160 to a portion of the front wiring patterns FM may be formed by passing through the first interlayer insulating film 180. The first epitaxial pattern 160 may electrically connect the first well region WR1 to the front wiring structure FW. A predetermined voltage may be applied to the first well region WR1 through the front wiring structure FW and the first epitaxial pattern 160.

The first doping region IR1 may be electrically connected to the front wiring structure FW and/or the backside wiring structure BW. For example, a first contact pattern 190 connecting the first doping region IR1 to another portion of the front wiring patterns FM may be formed by passing through the first interlayer insulating film 180. A predetermined voltage may be applied to the first doping region IR1 through the front wiring structure FW. In some embodiments, the first contact pattern 190 may be connected to the uppermost one from among the semiconductor films 111 to 113 (e.g., the first semiconductor film 113) in the first doping region IR1. In some embodiments, the first contact pattern 190 may be elongated in the second direction Y. In some embodiments, a plurality of first contact patterns 190 may be connected to the first doping region IR1.

In some embodiments, the first well region WR1, the first doping region IR1 and the front wiring structure FW may provide a PN diode.

A passive device such as a diode using a process of fabricating a semiconductor device including a multi-bridge channel has been proposed. For example, a PN junction using a well region in the base substrate may be provided, and a contact connected to an anode of the PN junction using an epitaxial pattern connected to the multi-bridge channel may be provided. However, such a PN junction has a problem in that it is difficult to be compatible with a so-called back side power delivery network (BSPDN) in which a power delivery network is provided from a back side of the base substrate. For example, in order to implement the back side power delivery network, a thinning process for the back side of the base substrate may be performed. The thinning process may be performed up to a lower surface of the shallow isolation trench (STI) formed on the base substrate, and in this case, the well region forming the PN junction in the base substrate may be removed.

On the other hand, the semiconductor device according to some embodiments may improve compatibility with the back side power delivery network by using the PN junction formed in the bulk semiconductor pattern 110. For example, as described above, the first well region WR1 and the first doping region IR1 may provide the PN junction in the bulk semiconductor pattern 110. The PN junction may be positioned at a level between the lower surface of the first device isolation pattern 105 and the upper surface of the bulk semiconductor pattern 110. Accordingly, even though the base substrate is removed by the thinning process for the backside power delivery network, the PN junction in the bulk semiconductor pattern 110 may be provided without problems. As a result, the semiconductor device including the passive device having improved compatibility with the backside power delivery network may be provided.

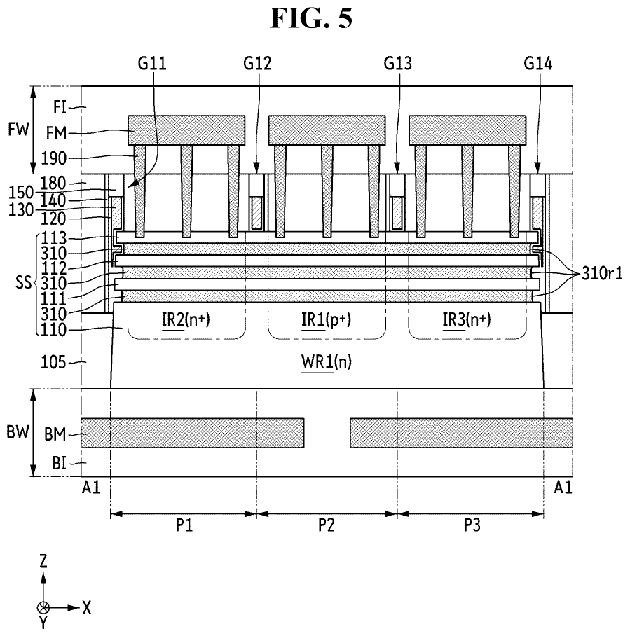

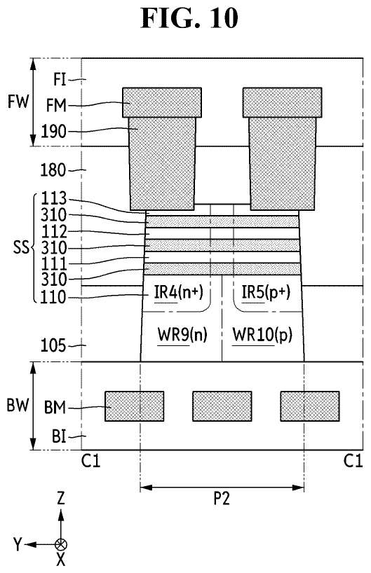

FIGS. 5 to 10 are various other cross-sectional views illustrating a semiconductor device according to some embodiments. For convenience of description, redundant descriptions given above with reference to FIGS. 1 to 4 may be briefly provided or omitted. For reference, FIGS. 5 to 9 are different cross-sectional views taken along the line A1-A1 of FIG. 1, and FIG. 10 is another cross-sectional view taken along the line C1-C1 of FIG. 1.

Referring to FIGS. 1 and 5, in the semiconductor device according to some embodiments, the stacked structure SS may include a first doping region IR1, a second doping region IR2, and a third doping region IR3.

The second doping region IR2 may be formed in the first portion P1 of the stacked structure SS. For example, the second doping region IR2 may be formed in the stacked structure SS between the first gate structure G11 and the second gate structure G12.

The third doping region IR3 may be formed in the third portion P3 of the stacked structure SS. For example, the third doping region IR3 may be formed in the stacked structure SS between the third gate structure G13 and the fourth gate structure G14.

Each of the second doping region IR2 and the third doping region IR3 may have the first conductivity type. For example, each of the second doping region IR2 and the third doping region IR3 may be a heavily doped n-type doping region n+ formed by doping heavily doped n-type impurities (e.g., P, Sb or As) in the stacked structure SS.

Each of the second doping region IR2 and the third doping region IR3 may be formed across the bulk semiconductor pattern 110, the first sacrificial films 310, and the first semiconductor films 111 to 113. Each of the second doping region IR2 and the third doping region IR3 may be directly connected to the first well region WR1.

Each of the second doping region IR2 and the third doping region IR3 may be electrically connected to the front wiring structure FW and/or the backside wiring structure BW. For example, at least one first contact pattern 190 connecting the second doping region IR2 and/or the third doping region IR3 to a portion of the front wiring patterns FM may be formed by passing through the first interlayer insulating film 180. The second doping region IR2 and the third doping region IR3 may electrically connect the first well region WR1 to the front wiring structure FW. A predetermined voltage may be applied to the first well region WR1 through the front wiring structure FW, the second doping region IR2, and the third doping region IR3.

In some embodiments, the first well region WR1, the first doping region IR1, and the front wiring structure FW may provide a PN diode.

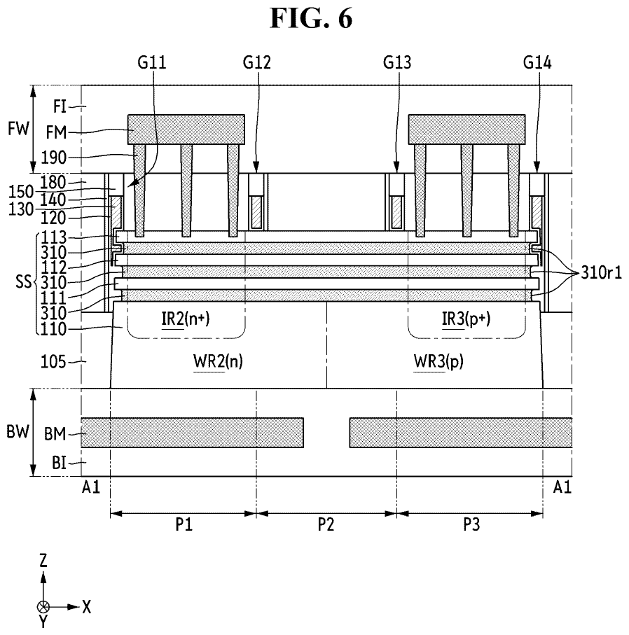

Referring to FIGS. 1 and 6, in the semiconductor device according to some embodiments, the bulk semiconductor pattern 110 may include a second well region WR2 and a third well region WR3.

The second well region WR2 may have the first conductivity type. For example, the second well region WR2 may be an n-type doping region “n” formed by doping n-type impurities (e.g., P, Sb, or As) in the bulk semiconductor pattern 110.

The third well region WR3 may have the second conductivity type. For example, the second well region WR2 may be a p-type doping region “p” formed by doping p-type impurities (e.g., B, In, Ga, or Al) in the bulk semiconductor pattern 110.

The second well region WR2 and the third well region WR3 may be directly connected to each other. For example, as shown in FIG. 6, the second well region WR2 and the third well region WR3 may be bonded to each other in the first direction X. Therefore, the second well region WR2 and the third well region WR3 may form a PN junction in the bulk semiconductor pattern 110.

In some embodiments, the stacked structure SS may include a second doping region IR2 and a third doping region IR3.

The second doping region IR2 may have the first conductivity type. For example, the second doping region IR2 may be a heavily doped n-type doping region n+ formed by doping heavily doped n-type impurities (e.g., P, Sb, or As) in the stacked structure SS. The second doping region IR2 may be formed across the bulk semiconductor pattern 110, the first sacrificial films 310, and the first semiconductor films 111 to 113. The second doping region IR2 may be directly connected to the second well region WR2.

The third doping region IR3 may have the second conductivity type. For example, the third doping region IR3 may be a heavily doped p-type doping region p+ formed by doping heavily doped p-type impurities (e.g., B, In, Ga, or Al) in the stacked structure SS. The third doping region IR3 may be formed across the bulk semiconductor pattern 110, the first sacrificial films 310, and the first semiconductor films 111 to 113. The third doping region IR3 may be directly connected to the third well region WR3.

The second doping region IR2 may electrically connect the second well region WR2 to the front wiring structure FW. A predetermined voltage may be applied to the second well region WR2 through the front wiring structure FW and the second doping region IR2.

The third doping region IR3 may electrically connect the third well region WR3 to the front wiring structure FW. A predetermined voltage may be applied to the third well region WR3 through the front wiring structure FW and the third doping region IR3.

In some embodiments, the second well region WR2, the third well region WR3, and the front wiring structure FW may provide a PN diode.

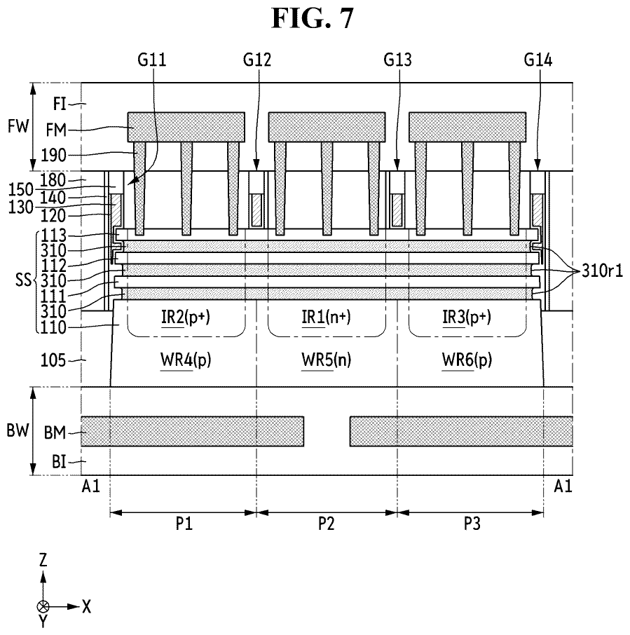

Referring to FIGS. 1 and 7, in the semiconductor device according to some embodiments, the bulk semiconductor pattern 110 may include a fourth well region WR4, a fifth well region WR5 and a sixth well region WR6.

The fourth well region WR4 may be formed in the first portion P1 of the bulk semiconductor pattern 110. The fourth well region WR4 may have the second conductivity type. For example, the fourth well region WR4 may be a p-type doping region “p” formed by doping p-type impurities (e.g., B, In, Ga, or Al) in the bulk semiconductor pattern 110.

The fifth well region WR5 may be formed in the second portion P2 of the bulk semiconductor pattern 110. The fifth well region WR5 may have the first conductivity type. For example, the fifth well region WR5 may be an n-type doping region “n” formed by doping n-type impurities (e.g., P, Sb, or As) in the bulk semiconductor pattern 110.

The sixth well region WR6 may be formed in the third portion P3 of the bulk semiconductor pattern 110. The sixth well region WR6 may have the second conductivity type. For example, the sixth well region WR6 may be a p-type doping region “p” formed by doping p-type impurities (e.g., B, In, Ga, or Al) in the bulk semiconductor pattern 110.

The fourth well region WR4 and the fifth well region WR5 may be directly connected to each other. For example, as shown in FIG. 7, the fourth well region WR4 and the fifth well region WR5 may be bonded to each other in the first direction X. Therefore, the fourth well region WR4 and the fifth well region WR5 may form a PN junction in the bulk semiconductor pattern 110.

The fifth well region WR5 and the sixth well region WR6 may be directly connected to each other. For example, as shown in FIG. 7, the fifth well region WR5 and the sixth well region WR6 may be bonded to each other in the first direction X. Accordingly, the fifth well region WR5 and the sixth well region WR6 may form a PN junction in the bulk semiconductor pattern 110.

In some embodiments, the stacked structure SS may include a first doping region IR1, a second doping region IR2, and a third doping region IR3.

The first doping region IR1 may have the first conductivity type. For example, the first doping region IR1 may be a heavily doped n-type doping region n+ formed by doping heavily doped n-type impurities (e.g., P, Sb, or As) in the stacked structure SS. The first doping region IR1 may be formed across the bulk semiconductor pattern 110, the first sacrificial films 310, and the first semiconductor films 111 to 113. The first doping region IR1 may be directly connected to the fifth well region WR5.

The second doping region IR2 may have the second conductivity type. For example, the second doping region IR2 may be a heavily doped p-type doping region p+ formed by doping heavily doped p-type impurities (e.g., B, In, Ga, or Al) in the stacked structure SS. The second doping region IR2 may be formed across the bulk semiconductor pattern 110, the first sacrificial films 310, and the first semiconductor films 111 to 113. The second doping region IR2 may be directly connected to the fourth well region WR4.

The third doping region IR3 may have the second conductivity type. For example, the third doping region IR3 may be a heavily doped p-type doping region p+ formed by doping heavily doped p-type impurities (e.g., B, In, Ga, or Al) in the stacked structure SS. The third doping region IR3 may be formed across the bulk semiconductor pattern 110, the first sacrificial films 310, and the first semiconductor films 111 to 113. The third doping region IR3 may be directly connected to the sixth well region WR6.

The first doping region IR1 may electrically connect the fifth well region WR5 to the front wiring structure FW. A predetermined voltage may be applied to the fifth well region WR5 through the front wiring structure FW and the first doping region IR1.

The second doping region IR2 may electrically connect the fourth well region WR4 to the front wiring structure FW. A predetermined voltage may be applied to the fourth well region WR4 through the front wiring structure FW and the second doping region IR2.

The third doping region IR3 may electrically connect the sixth well region WR6 to the front wiring structure FW. A predetermined voltage may be applied to the sixth well region WR6 through the front wiring structure FW and the third doping region IR3.

In some embodiments, the fourth well region WR4, the fifth well region WR5, the sixth well region WR6 and the front wiring structure FW may provide a bipolar junction transistor (e.g., a PNP transistor).

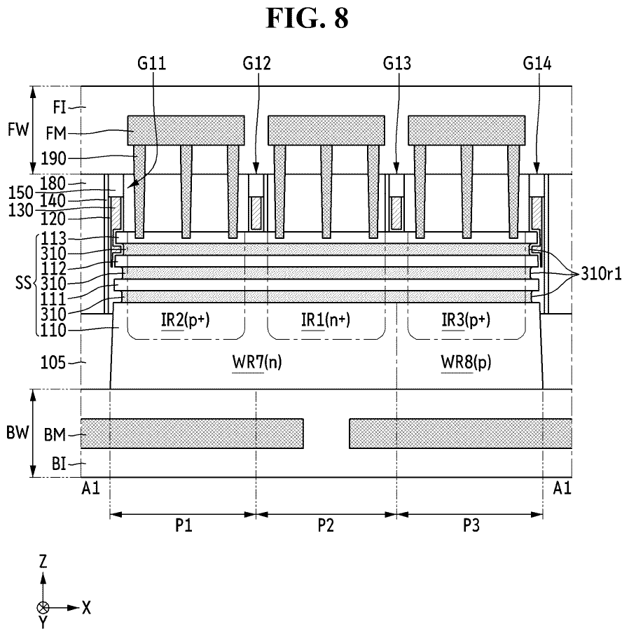

Referring to FIGS. 1 and 8, in the semiconductor device according to some embodiments, the bulk semiconductor pattern 110 may include a seventh well region WR7 and an eighth well region WR8.

The seventh well region WR7 may be formed in the first portion P1 and the second portion P2 of the bulk semiconductor pattern 110. The seventh well region WR7 may have the first conductivity type. For example, the seventh well region WR7 may be an n-type doping region “n” formed by doping n-type impurities (e.g., P, Sb, or As) in the bulk semiconductor pattern 110.

The eighth well region WR8 may be formed in the third portion P3 of the bulk semiconductor pattern 110. The eighth well region WR8 may have the second conductivity type. For example, the eighth well region WR8 may be a p-type doping region “p” formed by doping p-type impurities (e.g., B, In, Ga, or Al) in the bulk semiconductor pattern 110.

The seventh well region WR7 and the eighth well region WR8 may be directly connected to each other. For example, as shown in FIG. 8, the seventh well region WR7 and the eighth well region WR8 may be bonded to each other in the first direction X. Therefore, the seventh well region WR7 and the eighth well region WR8 may form a PN junction in the bulk semiconductor pattern 110.

In some embodiments, the stacked structure SS may include a first doping region IR1, a second doping region IR2, and a third doping region IR3.

The first doping region IR1 may have the first conductivity type. For example, the first doping region IR1 may be a heavily doped n-type doping region n+ formed by doping heavily doped n-type impurities (e.g., P, Sb, or As) in the stacked structure SS. The first doping region IR1 may be formed across the bulk semiconductor pattern 110, the first sacrificial films 310, and the first semiconductor films 111 to 113. The first doping region IR1 may be directly connected to the seventh well region WR7.

The second doping region IR2 may have the second conductivity type. For example, the second doping region IR2 may be a heavily doped p-type doping region p+ formed by doping heavily doped p-type impurities (e.g., B, In, Ga, or Al) in the stacked structure SS. The second doping region IR2 may be formed across the bulk semiconductor pattern 110, the first sacrificial films 310, and the first semiconductor films 111 to 113. The second doping region IR2 may be directly connected to the seventh well region WR7. Therefore, the seventh well region WR7 and the second doping region IR2 may form a PN junction in the bulk semiconductor pattern 110.

The third doping region IR3 may have the second conductivity type. For example, the third doping region IR3 may be a heavily doped p-type doping region p+ formed by doping heavily doped p-type impurities (e.g., B, In, Ga, or Al) in the stacked structure SS. The third doping region IR3 may be formed across the bulk semiconductor pattern 110, the first sacrificial films 310, and the first semiconductor films 111 to 113. The third doping region IR3 may be directly connected to the eighth well region WR8.

The first doping region IR1 may electrically connect the seventh well region WR7 to the front wiring structure FW. A predetermined voltage may be applied to the seventh well region WR7 through the front wiring structure FW and the first doping region IR1.

The third doping region IR3 may electrically connect the eighth well region WR8 to the front wiring structure FW. A predetermined voltage may be applied to the eighth well region WR8 through the front wiring structure FW and the third doping region IR3.

In some embodiments, the second doping region IR2, the seventh well region WR7, the eighth well region WR8, and the front wiring structure FW may provide a bipolar junction transistor (e.g., a PNP transistor).

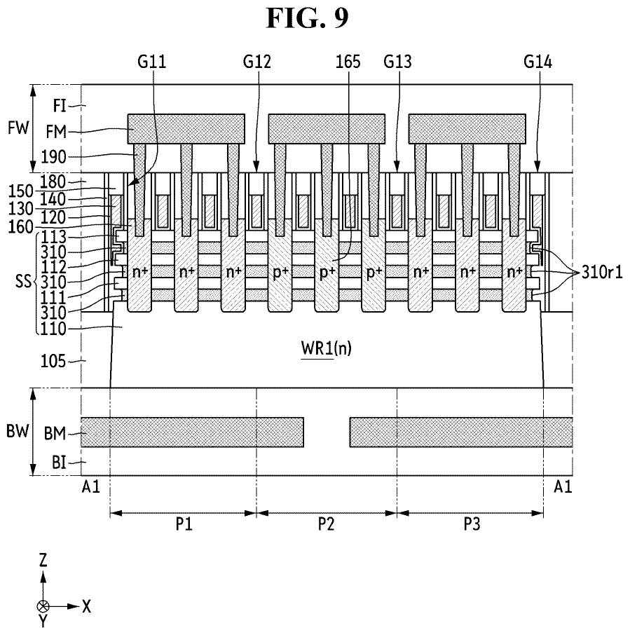

Referring to FIG. 9, the semiconductor device according to some embodiments further may include a second epitaxial pattern 165.

The second epitaxial pattern 165 may be formed on the stacked structure SS. In some embodiments, the second epitaxial pattern 165 may be formed on the second portion P2 of the stacked structure SS. For example, the second epitaxial pattern 165 may be formed in the stacked structure SS between the second gate structure G12 and the third gate structure G13. The second epitaxial pattern 165 may be connected to the upper surface of the bulk semiconductor pattern 110, the sides of the first sacrificial films 310, and the sides of the first semiconductor films 111 to 113. The second epitaxial pattern 165 may be separated from the first gate electrode 130 by the first gate dielectric film 120 and/or the first gate spacer 140. In some embodiments, the lowermost surface of the second epitaxial pattern 165 may be positioned to be lower than the uppermost surface of the bulk semiconductor pattern 110.

The second epitaxial pattern 165 may include an epitaxial layer doped with impurities. For example, the second epitaxial pattern 165 may be an epitaxial layer grown from the bulk semiconductor pattern 110, the first sacrificial films 310, and the first semiconductor films 111 to 113 by an epitaxial growth process.

In some embodiments, the second epitaxial pattern 165 may have the second conductivity type. For example, the second epitaxial pattern 165 may include p-type impurities (e.g., B, In, Ga, or Al) and/or impurities for preventing diffusion of the p-type impurities.

In some embodiments, the second epitaxial pattern 165 may further include a compressive stress material. For example, when each of the first semiconductor films 111 to 113 is a silicon (Si) film, the second epitaxial pattern 165 may include a material (e.g., silicon germanium (SiGe) having a lattice constant greater than a lattice constant of silicon (Si).

The second epitaxial pattern 165 may be directly connected to the first well region WR1. In some embodiments, the second epitaxial pattern 165 may be a heavily doped p-type doping region p+ formed by doping heavily doped p-type impurities. Therefore, the first well region WR1 and the second epitaxial pattern 165 may form a PN junction in the bulk semiconductor pattern 110.

The second epitaxial pattern 165 may be electrically connected to the front wiring structure FW and/or the backside wiring structure BW. For example, a first contact pattern 190 connecting the second epitaxial pattern 165 to a portion of the front wiring patterns FM may be formed by passing through the first interlayer insulating film 180. A predetermined voltage may be applied to the second epitaxial pattern 165 through the front wiring structure FW.

In some embodiments, the first well region WR1, the second epitaxial pattern 165, and the front wiring structure FW may provide a PN diode.

Referring to FIGS. 1 and 10, in the semiconductor device according to some embodiments, the bulk semiconductor pattern 110 may include a ninth well region WR9 and a tenth well region WR10.

The ninth well region WR9 may have the first conductivity type. For example, the ninth well region WR9 may be an n-type doping region “n” formed by doping n-type impurities (e.g., P, Sb, or As) in the bulk semiconductor pattern 110.

The tenth well region WR10 may have the second conductivity type. For example, the tenth well region WR10 may be a p-type doping region “p” formed by doping p-type impurities (e.g., B, In, Ga, or Al) in the bulk semiconductor pattern 110.

The ninth well region WR9 and the tenth well region WR10 may be directly connected to each other. For example, as shown in FIG. 10, the ninth well region WR9 and the tenth well region WR10 may be bonded to each other in the second direction Y. Therefore, the ninth well region WR9 and the tenth well region WR10 may form a PN junction in the bulk semiconductor pattern 110.

In some embodiments, the stacked structure SS may include a fourth doping region IR4 and a fifth doping region IR5.

The fourth doping region IR4 may have the first conductivity type. For example, the fourth doping region IR4 may be a heavily doped n-type doping region n+ formed by doping heavily doped n-type impurities (e.g., P, Sb, or As) in the stacked structure SS. The fourth doping region IR4 may be formed across the bulk semiconductor pattern 110, the first sacrificial films 310, and the first semiconductor films 111 to 113. The fourth doping region IR4 may be directly connected to the ninth well region WR9.

The fifth doping region IR5 may have the second conductivity type. For example, the fifth doping region IR5 may be a heavily doped p-type doping region p+ formed by doping heavily doped p-type impurities (e.g., B, In, Ga, or Al) in the stacked structure SS. The fifth doping region IR5 may be formed across the bulk semiconductor pattern 110, the first sacrificial films 310, and the first semiconductor films 111 to 113. The fifth doping region IR5 may be directly connected to the tenth well region WR10.

The fourth doping region IR4 may electrically connect the ninth well region WR9 to the front wiring structure FW. A predetermined voltage may be applied to the ninth well region WR9 through the front wiring structure FW and the fourth doping region IR4.

The fifth doping region IR5 may electrically connect the tenth well region WR10 to the front wiring structure FW. A predetermined voltage may be applied to the tenth well region WR10 through the front wiring structure FW and the fifth doping region IR5.

In some embodiments, the ninth well region WR9, the tenth well region WR10, and the front wiring structure FW may provide a PN diode.

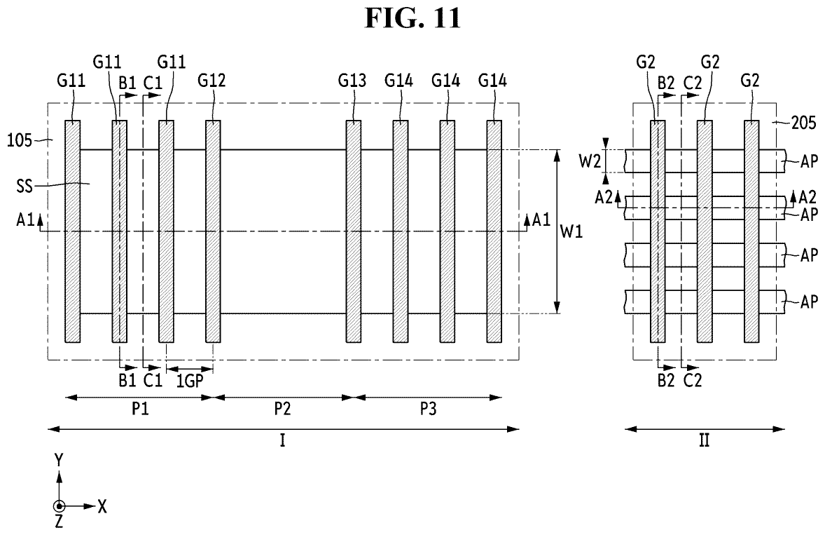

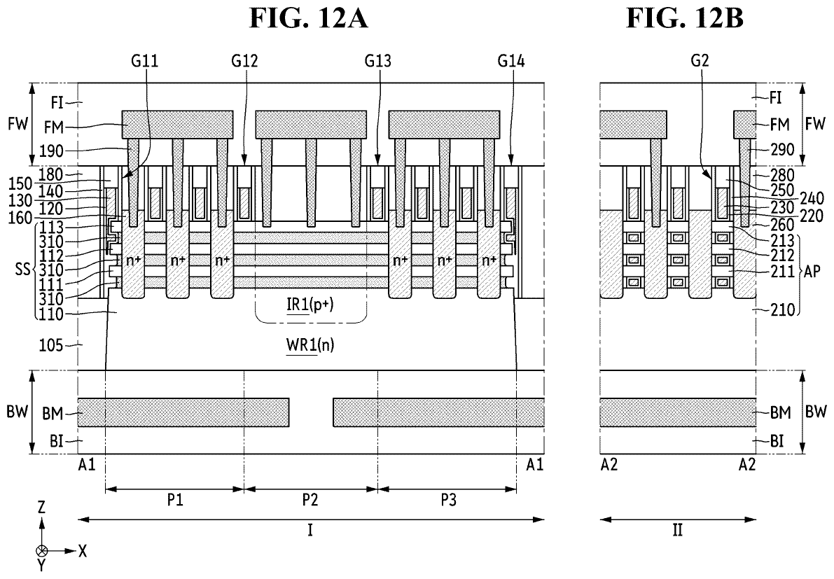

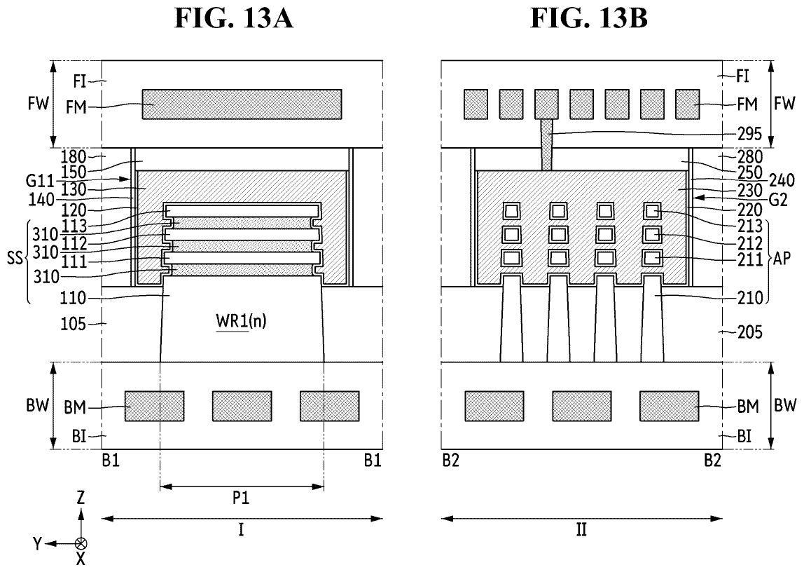

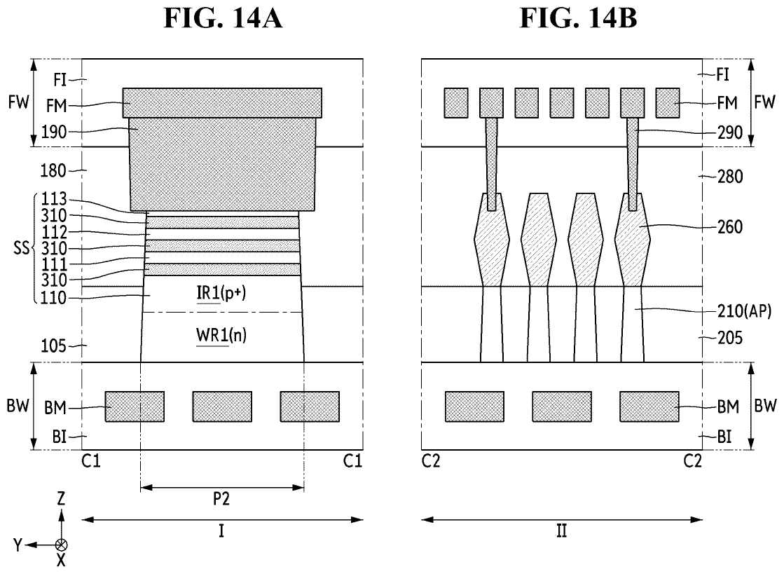

FIG. 11 is an example layout view illustrating a semiconductor device according to some embodiments. FIGS. 12A-B illustrate cross-sectional views taken along a line A1-A1 and a line A2-A2 of FIG. 11, respectively. FIGS. 13A-B illustrate cross-sectional views taken along a line B1-B1 and a line B2-B2 of FIG. 11, respectively. FIGS. 14A-B illustrate cross-sectional views taken along a line C1-C1 and a line C2-C2 of FIG. 11, respectively. For convenience of description, redundant descriptions given above with reference to FIGS. 1 to 10 may be briefly provided or omitted.

Referring to FIGS. 11 to 14B, the semiconductor device according to some embodiments includes a first region I and a second region II.

The first region I and the second region II may be regions adjacent to each other or spaced apart from each other. Although the first region I and the second region II are shown as being arranged along the first direction X, this is only an example, and the first region I and the second region II may be arranged along various other directions (e.g., the second direction Y).

In some embodiments, the first region I may be a region in which a band gap reference (BGR) generation circuit, an electrostatic discharge (ESD) protection circuit, a protection diode such as a transient voltage suppression (TVS) diode or a Zener diode, and/or a passive device such as a temperature sensor are disposed. In some embodiments, the second region II may be a region in which an active device such as a transistor is disposed.

The stacked structure SS, the first device isolation pattern 105, the first to fourth gate structures G11 to G14, the first epitaxial pattern 160, and the first interlayer insulating film 180 may be formed in the first region I. Although only the semiconductor device described with reference to FIGS. 1 to 4 is formed in the first region I, this is only an example, and a person with ordinary skill in the art to which the present disclosure pertains will understand that the semiconductor devices described with reference to FIGS. 5 to 10 may be formed in the first region I.

A plurality of active patterns AP, a second device isolation pattern 205, a fifth gate structure G2, a third epitaxial pattern 260, and a second interlayer insulating film 280 may be formed in the second region II.

The plurality of active patterns AP may be spaced apart from each other in the second direction Y. Each of the active patterns AP may be elongated in the first direction X. Each of the active patterns AP may include a fin-type pattern 210 and a plurality of second semiconductor films 211 to 213.

The fin-type pattern 210 may be positioned at a same level as the bulk semiconductor pattern 110. In the present specification, “positioned at the same level” means “positioned at the same height in a vertical direction (e.g., a third direction Z).” For example, a lower surface of the fin-type pattern 210 may be positioned to be coplanar with the lower surface of the bulk semiconductor pattern 110, and an upper surface of the fin-type pattern 210 may be positioned to be coplanar with the upper surface of the bulk semiconductor pattern 110.

The fin-type pattern 210 may be formed in the same process as the bulk semiconductor pattern 110. In the present specification, “formed in the same process” means “formed by the same fabricating process.” For example, the fin-type pattern 210 may have the same material (or the same material configuration) as a material (or a material configuration) of the bulk semiconductor pattern 110.

The plurality of second semiconductor films 211 to 213 may be stacked on the upper surface of the fin-type pattern 210 by being spaced apart from one another. Each of the second semiconductor films 211 to 213 may be elongated in the first direction X, and may be spaced apart from one another in the third direction Z. The second semiconductor films 211 to 213 may be used as a channel region of an MBCFET®, which includes a multi-bridge channel, on the second region II. The number, shape, arrangement, etc., of the second semiconductor films 211 to 213 are only examples, and are not limited to the shown example.

The plurality of second semiconductor films 211 to 213 may be positioned at the same level as the plurality of first semiconductor films 111 to 113, respectively. The plurality of second semiconductor films 211 to 213 may be formed in the same process as the plurality of first semiconductor films 111 to 113.

The second device isolation pattern 205 may cover at least a portion of a side of each of the active patterns AP. For example, as shown, the second device isolation pattern 205 may cover a portion of a side of the fin-type pattern 210.

The second device isolation pattern 205 may be positioned at the same level as the first device isolation pattern 105. The second device isolation pattern 205 may be formed in the same process as the first device isolation pattern 105.

The active patterns AP may have a shape that is defined by active patterns AP being divided by the second device isolation pattern 205. For example, a width W1 of the stacked structure SS in the second direction Y may be greater than a width W2 of each of the active patterns AP in the second direction Y. In some embodiments, the stacked structure SS may overlap the plurality of active patterns AP in the second direction Y.

The fifth gate structure G2 may be formed on the active patterns AP and the second device isolation pattern 205. The fifth gate structure G2 may cross the active patterns AP. For example, the fifth gate structure G2 may be elongated in the second direction Y. Each of the second semiconductor films 211 to 213 may extend in the first direction X to pass through the fifth gate structure G2. A plurality of fifth gate structures G2 may be spaced apart from each other in the first direction X.

The fifth gate structure G2 may include a second gate dielectric film 220, a second gate electrode 230, a second gate spacer 240, and a second gate capping film 250. The fifth gate structure G2 may be positioned at the same level as the first to fourth gate structures G11 to G14. The fifth gate structure G2 may be formed in the same process as the first to fourth gate structures G11 to G14. Since the second gate dielectric film 220, the second gate electrode 230, the second gate spacer 240, and the second gate capping film 250 may be similar to the first gate dielectric film 120, the first gate electrode 130, the first gate spacer 140 and the first gate capping film 150, respectively, repeated description thereof may be omitted below.

The third epitaxial pattern 260 may be formed on the active patterns AP. For example, the third epitaxial pattern 260 may be formed in the active patterns AP on at least one side of the fifth gate structure G2. The third epitaxial pattern 260 may be connected to the upper surface of the fin-type pattern 210 and sides of the second semiconductor films 211 to 213. The third epitaxial pattern 260 may be separated from the second gate electrode 230 by the second gate dielectric film 220 and/or the second gate spacer 240. In some embodiments, the lowermost surface of the third epitaxial pattern 260 may be positioned to be lower than the uppermost surface of the fin-type pattern 210.

The third epitaxial pattern 260 may include an epitaxial layer doped with impurities. For example, the third epitaxial pattern 260 may be an epitaxial layer grown from the fin-type pattern 210 and the second semiconductor films 211 to 213 by an epitaxial growth process.

When the second region II is an NFET region, the third epitaxial pattern 260 may include n-type impurities (e.g., P, Sb or As) and/or impurities for preventing diffusion of the n-type impurities. In some embodiments, the third epitaxial pattern 260 may further include a tensile stress material. For example, when each of the second semiconductor films 211 to 213 is a silicon (Si) pattern, the third epitaxial pattern 260 may include a material (e.g., silicon carbide (SiC) having a lattice constant smaller than a lattice constant of silicon (Si).

When the second region II is a PFET region, the third epitaxial pattern 260 may include p-type impurities (e.g., B, In, Ga or Al) and/or impurities for preventing diffusion of the p-type impurities. In some embodiments, the third epitaxial pattern 260 may further include a compressive stress material. For example, when each of the second semiconductor films 211 to 213 is a silicon (Si) pattern, the third epitaxial pattern 260 may include a material (e.g., silicon germanium (SiGe) having a lattice constant greater than the lattice constant of silicon (Si).

As shown in FIG. 14B, in a cross-section crossing the first direction X, the third epitaxial pattern 260 is shown as being hexagonal, but this is only an example. The third epitaxial pattern 260 may have various cross-sections, such as a pentagon and a diamond shape, depending on conditions of the epitaxial growth process.

The second interlayer insulating film 280 may be formed on the active patterns AP, the second device isolation pattern 205, the fifth gate structure G2, and the third epitaxial pattern 260. The second interlayer insulating film 280 may be formed to fill a space on an outer side of the fifth gate structure G2.

The second interlayer insulating film 280 may be positioned at the same level as the first interlayer insulating film 180. The second interlayer insulating film 280 may be formed in the same process as the first interlayer insulating film 180.

The third epitaxial pattern 260 may be electrically connected to the front wiring structure FW and/or the backside wiring structure BW. For example, the second contact pattern 290 connecting the third epitaxial pattern 260 to a portion of the front wiring patterns FM may be formed by passing through the second interlayer insulating film 280.

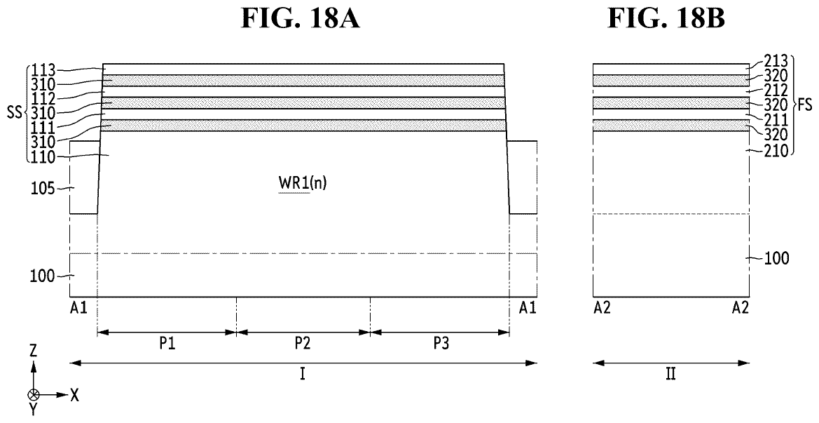

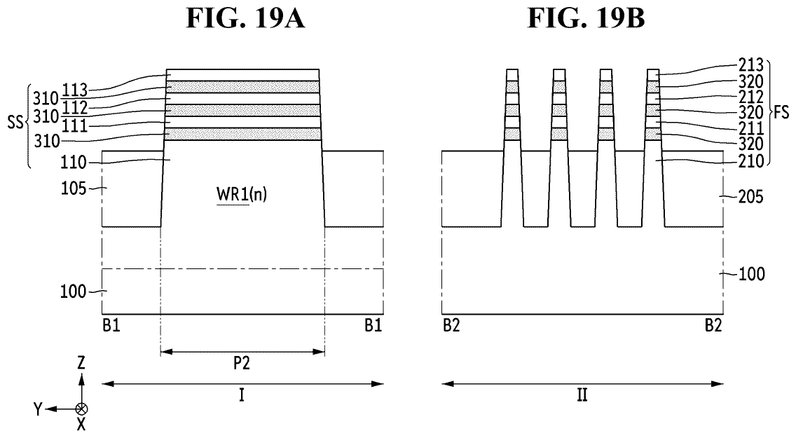

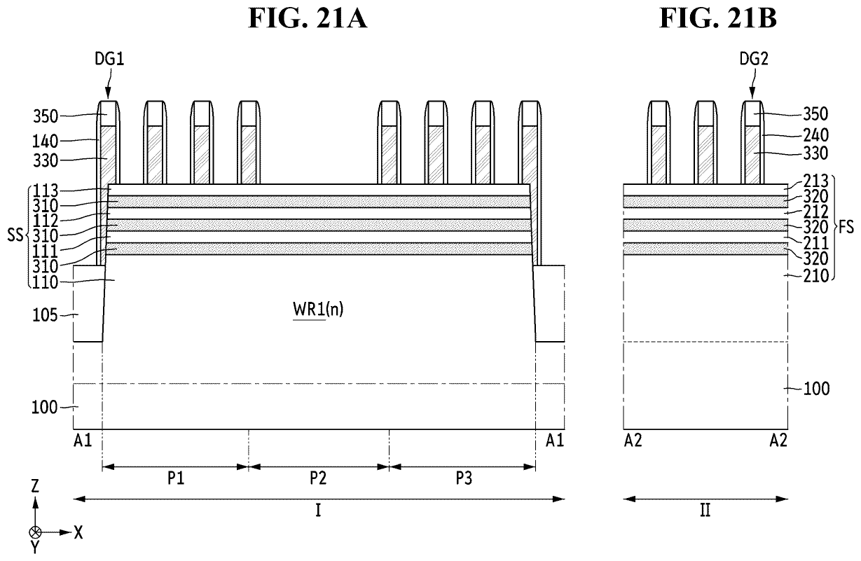

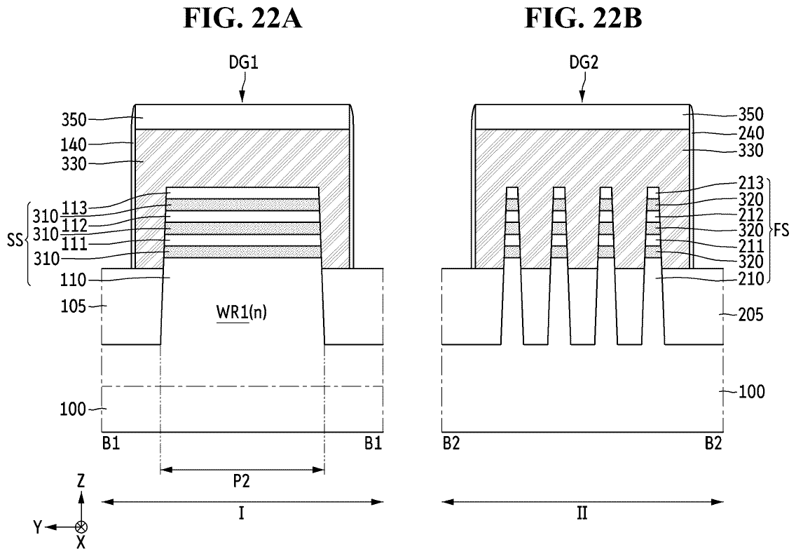

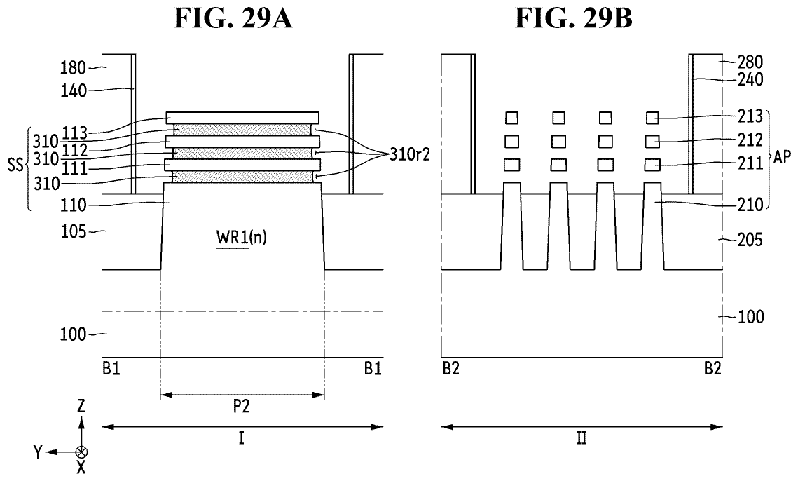

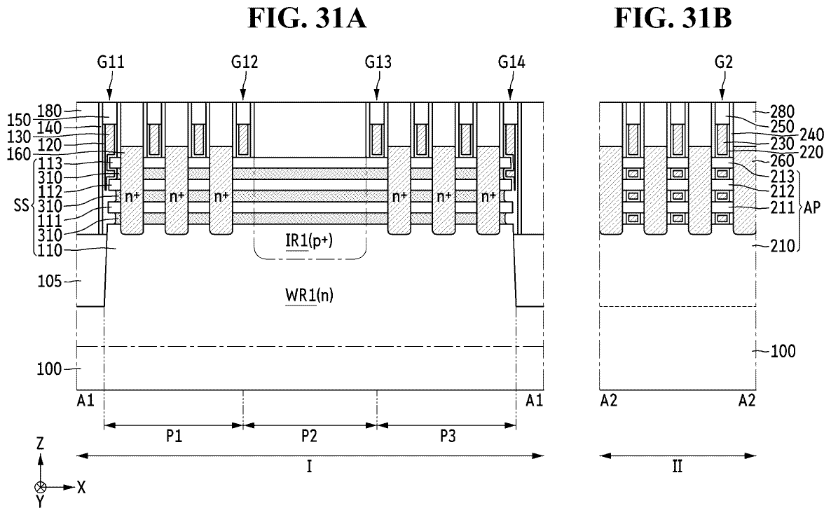

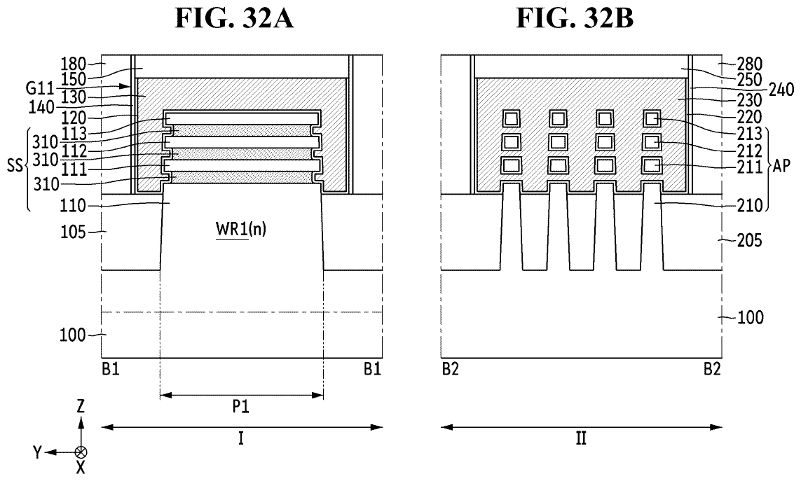

Hereinafter, a method for fabricating a semiconductor device according to example embodiments will be described with reference to FIGS. 1 to 36B.

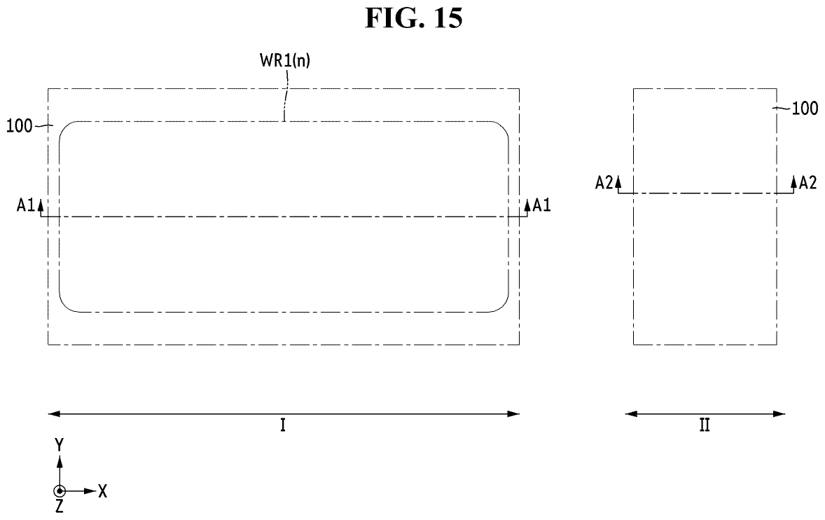

FIGS. 15 to 36B are views illustrating intermediate steps to describe a method for fabricating a semiconductor device according to some embodiments. For convenience of description, redundant descriptions given above with reference to FIGS. 1 to 14 may be briefly provided or omitted.

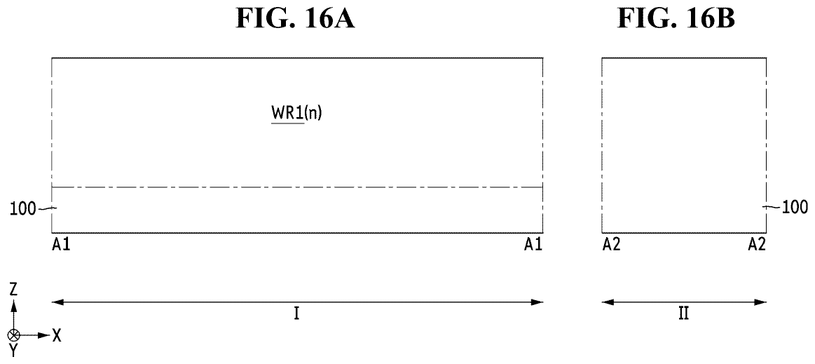

Referring to FIGS. 15 and 16A-B, a first well region WR1 may be formed in a base substrate 100.

The base substrate 100 may be a bulk silicon or a silicon-on-insulator (SOI). Alternatively, the base substrate 100 may be a silicon substrate, or may include another material such as, for example, silicon germanium, a silicon germanium-on-insulator (SGOI), indium antimonide, lead telluride, indium arsenide, indium phosphide, gallium arsenide, or gallium antimonide. In the following description, the base substrate 100 is a silicon (Si) substrate by way of example.

The first well region WR1 may be formed in the base substrate 100 of the first region I. For example, an ion implantation process for doping n-type impurities (e.g., P, Sb or As) in the base substrate 100 of the first region I may be performed.

Although the base substrate 100 in the second region II is shown as not being doped, this is only an example. As another example, when the second region II is a PFET region, the base substrate 100 in the first region I may be also doped with n-type impurities (e.g., P, Sb or As).

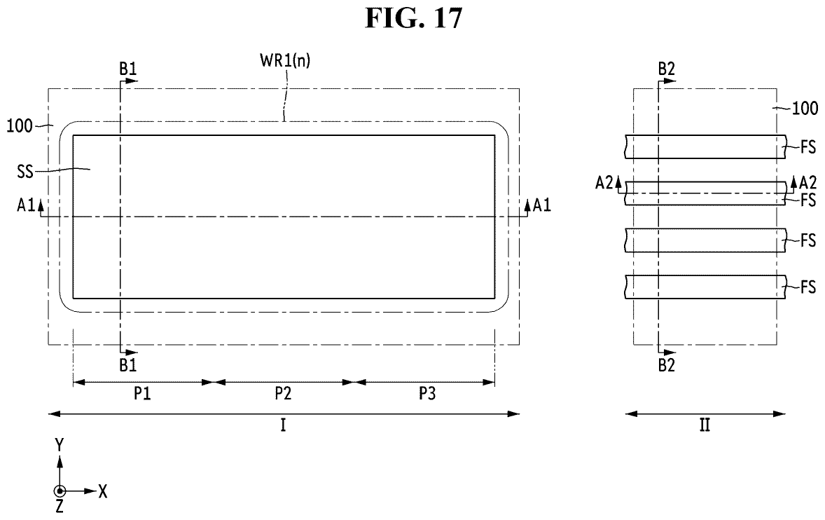

Referring to FIGS. 17 to 19B, the stacked structure SS may be formed in the first region I, and a plurality of fin structures FS may be formed in the second region II.

For example, sacrificial films and semiconductor films, which are alternately stacked on an upper surface of the base substrate 100, may be formed. The sacrificial films may include a material having etch selectivity with respect to the semiconductor films. For example, each of the semiconductor films may be a silicon (Si) film, and each of the sacrificial films may be a silicon germanium (SiGe) film. Subsequently, a patterning process of patterning the base substrate 100, the sacrificial films, and the semiconductor films may be performed. As a result, the stacked structure SS, which may include a bulk semiconductor pattern 110, a plurality of first sacrificial films 310, and a plurality of first semiconductor films 111 to 113, may be formed on the base substrate 100 in the first region I. Also, the plurality of fin structures FS, each of which may include a fin-type pattern 210, a plurality of second sacrificial films 320, and a plurality of second semiconductor films 211 to 213, may be formed on the base substrate 100 in the second region II. Each of the bulk semiconductor pattern 110 and the fin-type pattern 210 may be formed by etching a portion of the base substrate 100.

After the stacked structure SS and the plurality of fin structures FS are formed, the first device isolation pattern 105 and the second device isolation pattern 205 may be formed. The first device isolation pattern 105 may cover at least a portion of the side of the stacked structure SS. The second device isolation pattern 205 may cover at least a portion of a side of each of the fin structures FS.

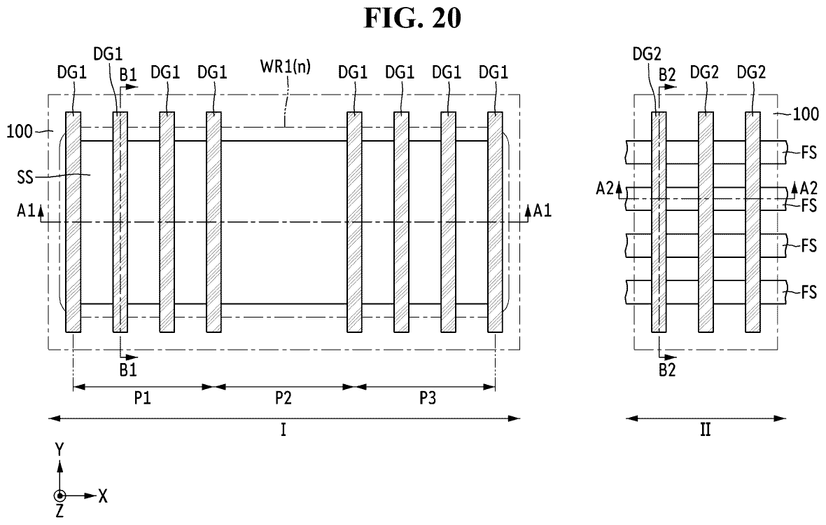

Referring to FIGS. 20 to 22B, a plurality of first dummy gate structures DG1 may be formed on the stacked structure SS, and a plurality of second dummy gate structures DG2 may be formed on the fin structures FS.

Each of the first dummy gate structures DG1 may cross the stacked structure SS. Each of the second dummy gate structures DG2 may cross the fin structures FS. For example, each of the first dummy gate structures DG1 and the second dummy gate structures DG2 may be elongated in the second direction Y.

Each of the first dummy gate structures DG1 may include a dummy gate electrode 330, a mask pattern 350, and a first gate spacer 140. Each of the second dummy gate structures DG2 may include a dummy gate electrode 330, a mask pattern 350, and a second gate spacer 240. A material film may be formed on the stacked structure SS and the fin structures FS. Subsequently, the mask pattern 350 elongated in the second direction Y may be formed on the material film. Subsequently, a patterning process of patterning the material film may be performed using the mask pattern 350 as an etching mask. As a result, the dummy gate electrode 330 may be formed from the material film. The first gate spacer 140 may extend along a side of the dummy gate electrode 330 on the stacked structure SS. The second gate spacer 240 may extend along a side of the dummy gate electrode 330 on the fin structures FS.

The dummy gate electrode 330 may include a material having etch selectivity with respect to the first semiconductor films 111 to 113 and the second semiconductor films 211 to 213. For example, the dummy gate electrode 330 may be a polysilicon pattern.

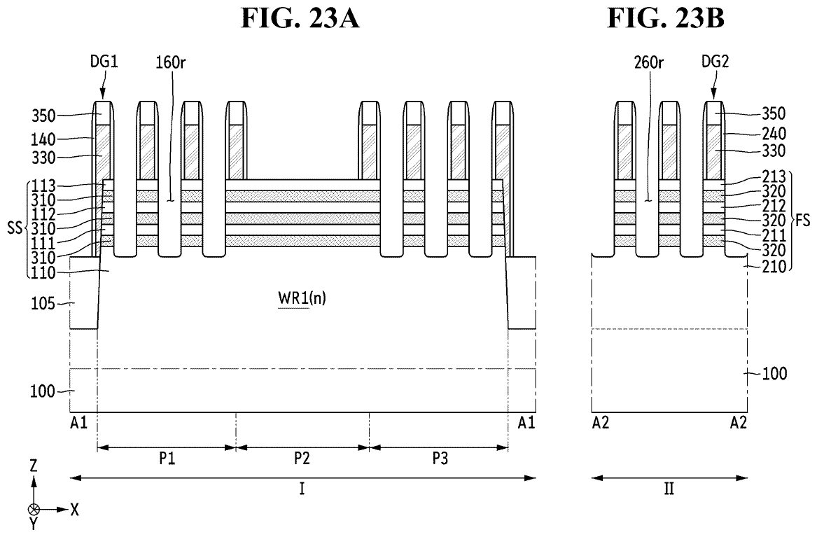

Referring to FIGS. 23A-B, at least one first source/drain recess 160r and at least one second source/drain recess 260r may be formed.

The at least one first source/drain recess 160r may be formed in the first portion P1 and the third portion P3 of the stacked structure SS. The at least one second source/drain recess 260r may be formed in each of the fin structures FS. In the process of forming the at least one first source/drain recess 160r and the at least one second source/drain recess 260r, the second portion P2 of the stacked structure SS may be protected. For example, a masking process of selectively exposing the first portion P1 and the third portions P3 of the stacked structure SS and the fin structures FS, and covering the second portion P2 of the stacked structure SS, may be performed. Subsequently, a recess process may be performed for the first portion P1 and the third portion P3 of the stacked structure SS and the fin structures FS by using the first dummy gate structures DG1 and the second dummy gate structures DG2 as etching masks.

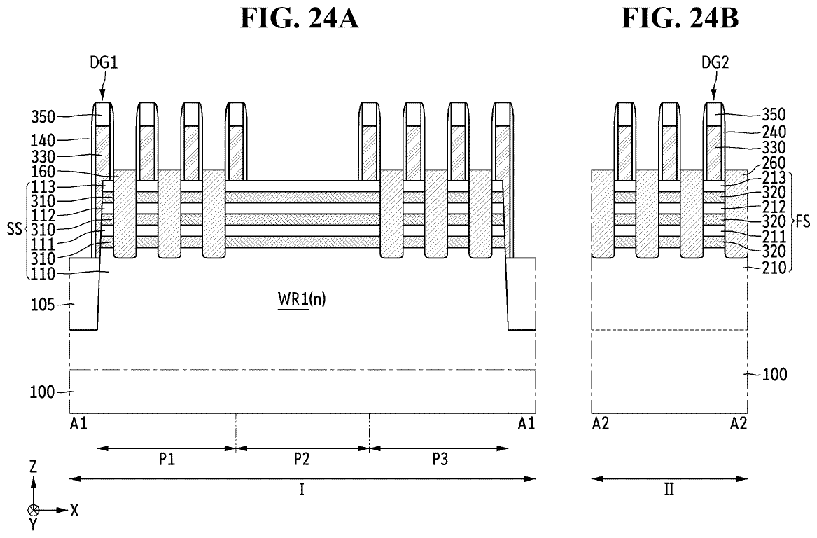

Referring to FIGS. 24A-B, a first epitaxial pattern 160 and a third epitaxial pattern 260 may be formed.

The first epitaxial pattern 160 may fill the first source/drain recess 160r of FIG. 23. For example, the first epitaxial pattern 160 may be grown from the bulk semiconductor pattern 110, the first sacrificial films 310, and the first semiconductor films 111 to 113 by an epitaxial growth process.

The third epitaxial pattern 260 may fill the second source/drain recess 260r of FIG. 23. For example, the third epitaxial pattern 260 may be grown from the fin-type pattern 210, the second sacrificial films 320, and the second semiconductor films 211 to 213 by an epitaxial growth process.

The first epitaxial pattern 160 and the third epitaxial pattern 260 may be formed in the same process or in different processes. In some embodiments, when the first epitaxial pattern 160 and the third epitaxial pattern 260 have the same conductivity type (e.g., the first conductivity type), the first epitaxial pattern 160 and the third epitaxial pattern 260 may be formed in the same process.

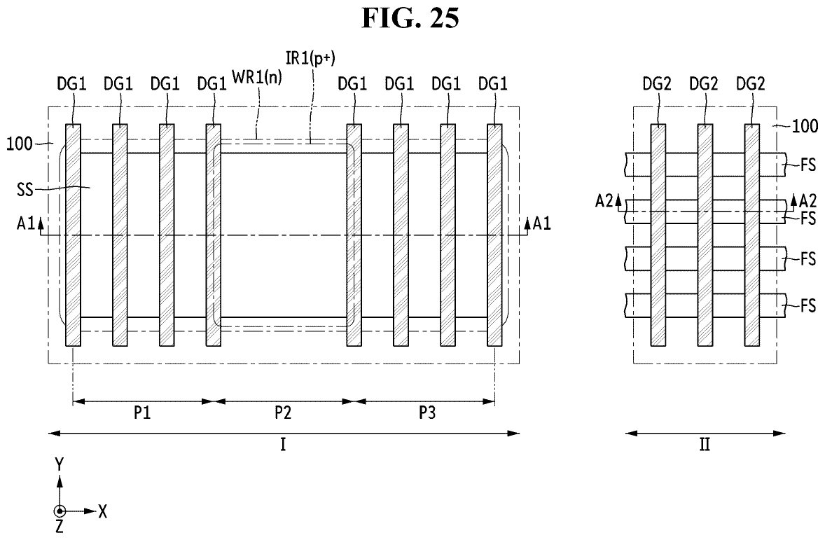

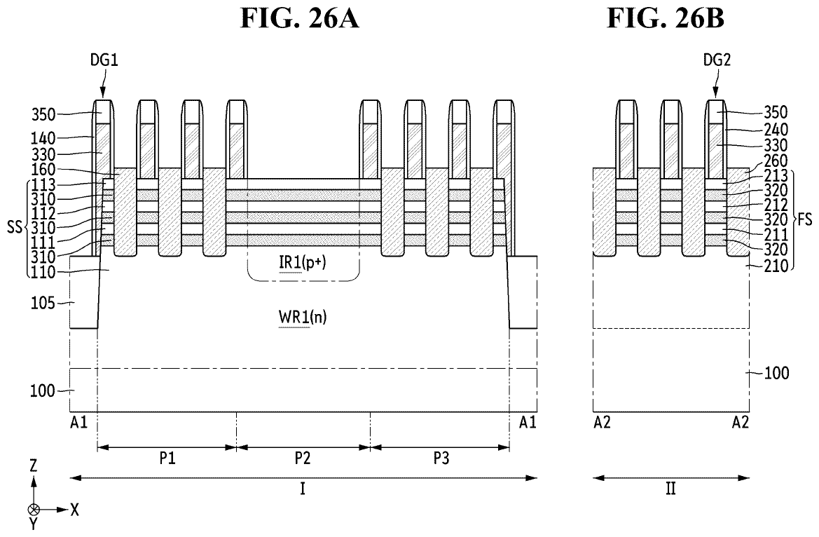

Referring to FIGS. 25 and 26A-B, a first doping region IR1 may be formed.

The first doping region IR1 may be formed in the second portion P2 of the stacked structure SS. For example, an ion implantation process of doping heavily doped p-type impurities (e.g., B, In, Ga or Al) in the second portion P2 of the stacked structure SS may be performed.

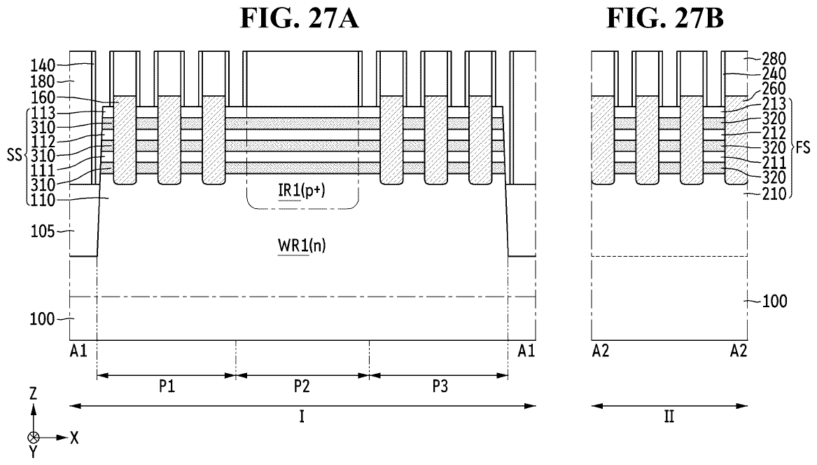

Referring to FIGS. 27A-B, the dummy gate electrode 330 may be removed.

For example, a first interlayer insulating film 180 filling a space on an outer side of the first dummy gate structures DG1 and a second interlayer insulating film 280 filling a space on an outer side of the second dummy gate structures DG2 may be formed. Subsequently, a planarization process for exposing the dummy gate electrode 330 may be performed. The dummy gate electrode 330 exposed by the planarization process may be selectively removed with respect to the first semiconductor films 111 to 113 and the second semiconductor films 211 to 213.

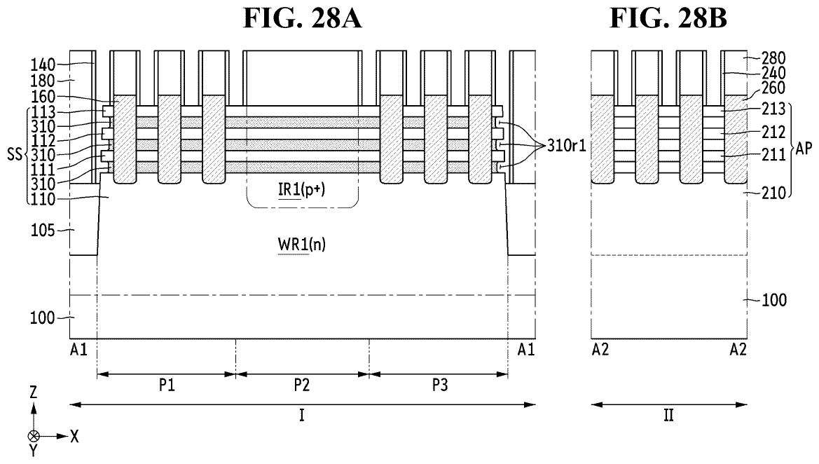

Referring to FIGS. 28A-B and 29A-B, the second sacrificial films 320 may be removed.

The second sacrificial films 320 may be selectively removed with respect to the second semiconductor films 211 to 213. In the process of removing the second sacrificial films 320, the first sacrificial films 310 may not be completely removed. In detail, unlike the fin structures FS divided by the second device isolation pattern 205, the stacked structure SS may have a bulk shape that is not divided by the first device isolation pattern 105. Therefore, an etchant of the etching process for removing the second sacrificial films 320 may not easily remove the first sacrificial films 310.

In some embodiments, each of the first sacrificial films 310 may include a first recess 310r1 and a second recess 310r2. The first recess 310r1 and the second recess 310r2 may be formed by removing a portion of the first sacrificial films 310 exposed in the etching process for removing the second sacrificial films 320.

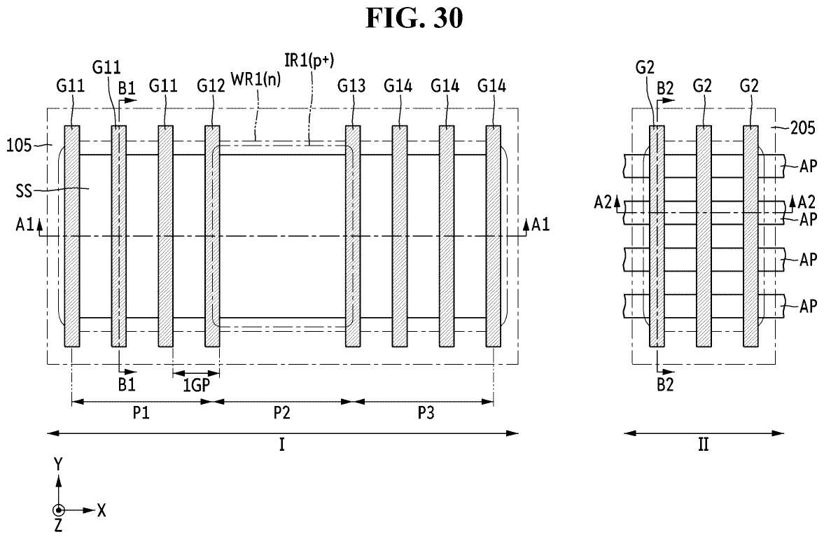

Referring to FIGS. 30 to 32B, first to fourth gate structures G11 to G14 and a fifth gate structure G2 may be formed.

For example, a dielectric film and a conductive film may be sequentially stacked in a region from which the dummy gate electrode 330 is removed and a region from which the second sacrificial films 320 are removed. Also, a capping film covering an upper surface of the conductive film may be formed. As a result, the first to fourth gate structures G11 to G14, which may include a first gate dielectric film 120, a first gate electrode 130, a first gate spacer 140, and a first gate capping film 150, may be formed. Also, the fifth gate structure G2, which may include a second gate dielectric film 220, a second gate electrode 230, a second gate spacer 240 and a second gate capping film 250, may be formed.

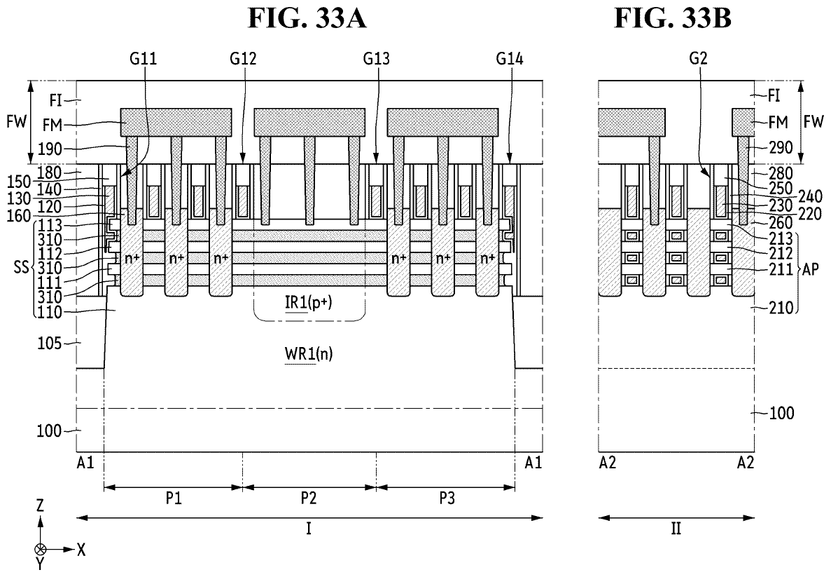

Referring to FIGS. 33A-B, a first contact pattern 190, a second contact pattern 290, and a front wiring structure FW may be formed.

The first contact pattern 190 may be connected to the first epitaxial pattern 160 and/or the first doping region IR1. The second contact pattern 290 may be connected to the third epitaxial pattern 260. The front wiring structure FW may be electrically connected to the first contact pattern 190 and/or the second contact pattern 290.

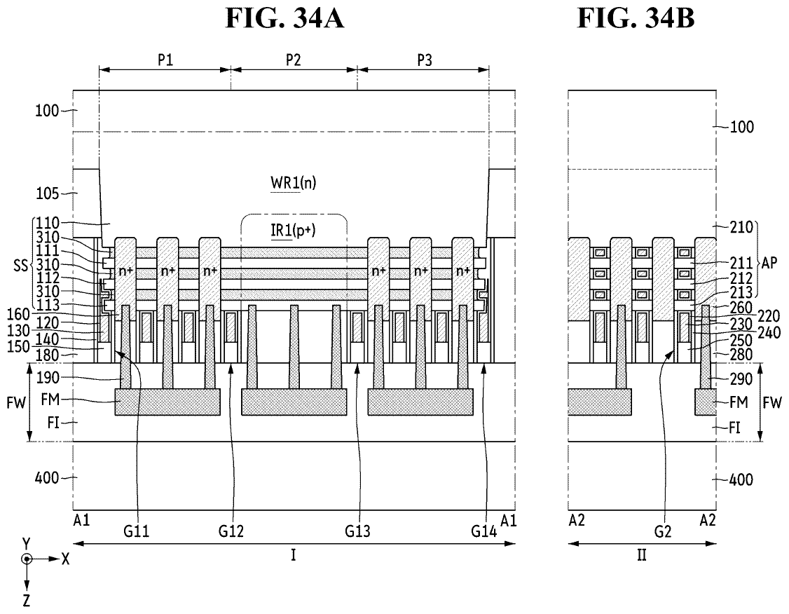

Referring to FIGS. 34A-B, the front wiring structure FW may be attached onto a carrier substrate 400.

For example, the carrier substrate 400 may be attached onto the resultant of FIGS. 33A-B. After the carrier substrate 400 is attached, the resultant of FIGS. 33A-B may be inverted.

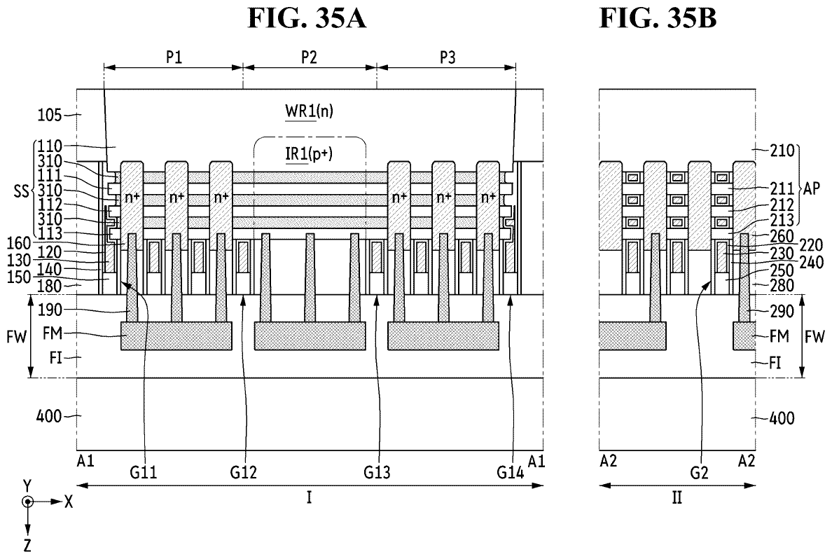

Referring to FIGS. 35A-B, the base substrate 100 may be removed.

For example, a thinning process may be performed for the base substrate 100. The thinning process may include, for example, a back grinding process for the back side of the base substrate 100, but is not limited thereto. As the thinning process is performed, the first device isolation pattern 105 and/or the second device isolation pattern 205 may be exposed. In some embodiments, a surface of the first device isolation pattern 105 may be disposed to be coplanar with a surface of the bulk semiconductor pattern 110.

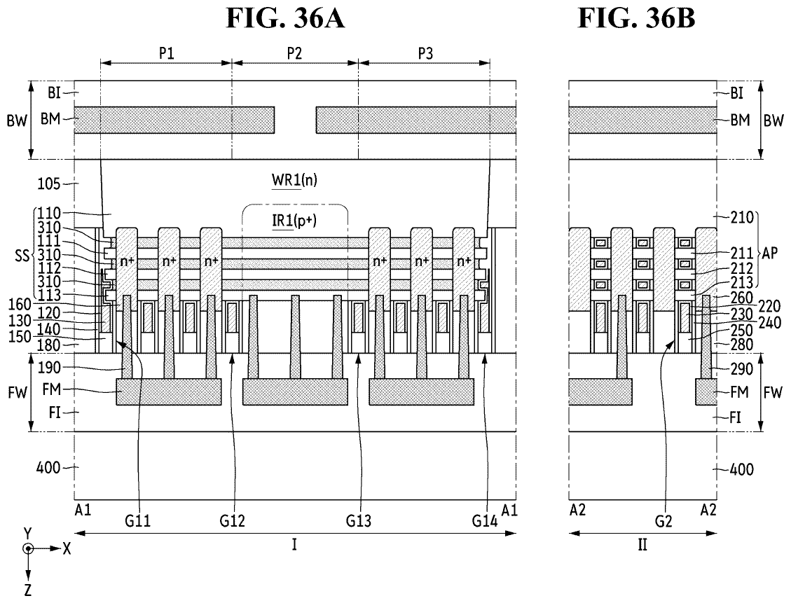

Referring to FIGS. 36A-B, a backside wiring structure BW may be formed on the bulk semiconductor pattern 110, the first device isolation pattern 105, the fin-type pattern 210, and the second device isolation pattern 205.

Subsequently, referring to FIG. 2, the carrier substrate 400 may be removed. As a result, the semiconductor device described with reference to FIGS. 1 to 4 may be fabricated.

While non-limiting example embodiments of the present disclosure have been described with reference to the accompanying drawings, it will be understood by those of ordinary skill in the art that various changes in form and details may be made therein without departing from the spirit and scope of the present disclosure. The present example embodiments should be considered in all respects as illustrative and not restrictive.

What is claimed is:

1. A semiconductor device comprising:
a stacked structure comprising:
a bulk semiconductor pattern comprising a first well region;
a sacrificial film on an upper surface of the bulk semiconductor pattern; and
a semiconductor film on an upper surface of the sacrificial film;
a device isolation pattern on a side of the stacked structure; and
a backside wiring structure on a lower surface of the bulk semiconductor pattern and a lower surface of the device isolation pattern,
wherein the stacked structure further comprises a first doping region that extends across the bulk semiconductor pattern, the sacrificial film, and the semiconductor film, and the first doping region is connected to the first well region, and
wherein the first doping region is spaced apart from the lower surface of the bulk semiconductor pattern.

2. The semiconductor device of claim 1, wherein the first well region has a first conductivity type, and
wherein the first doping region has a second conductivity type different from the first conductivity type.

3. The semiconductor device of claim 2, wherein the stacked structure further comprises a second doping region that extends across the bulk semiconductor pattern, the sacrificial film, and the semiconductor film, and the second doping region is connected to the first well region, and
wherein the second doping region has the first conductivity type.

4. The semiconductor device of claim 3, wherein a doping concentration of the second doping region is higher than a doping concentration of the first well region.

5. The semiconductor device of claim 1, wherein the bulk semiconductor pattern further comprises a second well region connected to the first well region,
wherein the first well region has a first conductivity type, and
wherein the second well region has a second conductivity type different from the first conductivity type.

6. The semiconductor device of claim 5, wherein the first well region and the second well region are disposed, with respect to each other, in a horizontal direction that is parallel with the upper surface of the bulk semiconductor pattern.

7. The semiconductor device of claim 1, wherein the lower surface of the bulk semiconductor pattern is coplanar with or higher than the lower surface of the device isolation pattern.

8. The semiconductor device of claim 1, wherein the bulk semiconductor pattern comprises a silicon pattern.

9. The semiconductor device of claim 1, wherein the sacrificial film comprises a silicon germanium film, and
wherein the semiconductor film includes a silicon film.

10. The semiconductor device of claim 1, wherein the first doping region is formed by an ion implantation process of the stacked structure.

11. A semiconductor device comprising:
a stacked structure comprising:
a bulk semiconductor pattern comprising a first well region having a first conductivity type;
a sacrificial film on an upper surface of the bulk semiconductor pattern; and
a semiconductor film on an upper surface of the sacrificial film;
a device isolation pattern on a side of the stacked structure; and
a gate structure on the stacked structure and the device isolation pattern, and crossing the stacked structure,
wherein the stacked structure further comprises a first doping region on a first side of the gate structure, the first doping region connected to the first well region and having a second conductivity type different from the first conductivity type, and
wherein the first doping region extends across the bulk semiconductor pattern, the sacrificial film, and the semiconductor film.

12. The semiconductor device of claim 11, further comprising an epitaxial pattern in the stacked structure on a second side of the gate structure, opposite of the first side, the epitaxial pattern connected to the first well region and having the first conductivity type.

13. The semiconductor device of claim 11, further comprising a second doping region on the second side of the gate structure, the second doping region connected to the first well region and having the first conductivity type, and
wherein the second doping region extends across the bulk semiconductor pattern, the sacrificial film, and the semiconductor film.

14. The semiconductor device of claim 13, wherein a doping concentration of the second doping region is higher than a doping concentration of the first well region.

15. The semiconductor device of claim 11, further comprising a backside wiring structure on a lower surface of the bulk semiconductor pattern and a lower surface of the device isolation pattern.

16. The semiconductor device of claim 11, wherein a side of the sacrificial film, which faces towards the gate structure, comprises a recess that is recessed past a side of the semiconductor film, which faces towards the gate structure.

17. A semiconductor device comprising:
a stacked structure in a first region of the semiconductor device, the stacked structure comprising:
a bulk semiconductor pattern;
a sacrificial film on an upper surface of the bulk semiconductor pattern; and
a first semiconductor film on an upper surface of the sacrificial film;
an active pattern comprising a fin-type pattern and a second semiconductor film in a second region of the semiconductor device, the fin-type pattern extending in a first direction, and the second semiconductor film extending in the first direction and spaced apart from an upper surface of the fin-type pattern;
a device isolation pattern on a side of the bulk semiconductor pattern and a side of the fin-type pattern;
a first gate structure on the stacked structure and the device isolation pattern, and crossing the stacked structure;
a second gate structure on the active pattern and the device isolation pattern, and extending in a second direction crossing the first direction; and
a backside wiring structure on a lower surface of the bulk semiconductor pattern, a lower surface of the fin-type pattern, and a lower surface of the device isolation pattern,
wherein the bulk semiconductor pattern and the fin-type pattern are at a same level as each other,
wherein the first semiconductor film and the second semiconductor film are at a same level as each other, and
wherein the stacked structure further comprises a PN junction at a level between the lower surface of the device isolation pattern and the upper surface of the bulk semiconductor pattern.

18. The semiconductor device of claim 17, wherein each of the lower surface of the bulk semiconductor pattern and the lower surface of the fin-type pattern is coplanar with or higher than the lower surface of the device isolation pattern.

19. The semiconductor device of claim 17, wherein the PN junction comprises:
a well region in the bulk semiconductor pattern and having a first conductivity type; and
a doping region extending across the bulk semiconductor pattern, the sacrificial film, and the first semiconductor film, and
wherein the doping region having a second conductivity type different from the first conductivity type.

20. The semiconductor device of claim 17, wherein the PN junction comprises:
a first well region in the bulk semiconductor pattern and having a first conductivity type; and
a second well region in the bulk semiconductor pattern and having a second conductivity type different from the first conductivity type.
